(19) United States
(12) Patent Application Publication
(10) Pub. No.: US 2017/0117264 A1
(43) Pub. Date: Apr. 27, 2017

(54) STACKED SEMICONDUCTOR PACKAGE AND METHOD OF FABRICATING THE SAME

(71) Applicant: Samsung Electronics Co., Ltd., Suwon-si (KR)

(72) Inventors: In-young Lee, Yongin-si (KR); Hyun-soo Chung, Hwaseong-si (KR); Tae-je Cho, Yongin-si (KR)

(21) Appl. No.: 15/285,500

(22) Filed: Oct. 5, 2016

(30) Foreign Application Priority Data
Oct. 21, 2015 (KR) 10-2015-0146664

(51) Int. Cl. H01L 25/00; H01L 23/00

(52) U.S. Cl. CPC H01L 25/50; H01L 24/03; H01L 24/17; H01L 2224/0231; H01L 2224/02379

(57) ABSTRACT

A method may include providing a first semiconductor chip and a first insulating layer surrounding lateral sides of the first semiconductor chip; providing a second semiconductor chip and a second insulating layer surrounding lateral sides of the second semiconductor chip; providing a third insulating layer below the first semiconductor chip and first insulating layer, so that the first semiconductor chip is between the third insulating layer and the second semiconductor chip, the third insulating layer forming a package substrate; providing a plurality of external connection terminals on the third insulating layer, such that the third insulating layer has a first surface facing the first semiconductor chip and a second surface facing the external connection terminals; providing a first redistribution line on the first surface of the third insulating layer and extending horizontally along the first surface of the third insulating layer, the first redistribution line contacting a first conductive pad of the first semiconductor chip; and providing a second redistribution line connected to a second conductive pad at a surface of the second semiconductor chip, the second redistribution line passing through the first insulating layer to contact the first redistribution line.

### CROSS-REFERENCE TO RELATED APPLICATION

This application claims the benefit of priority under 35 U.S.C. §119 to Korean Patent Application No. 10-2015-0146664, filed on Oct. 21, 2015, in the Korean Intellectual Property Office, the disclosure of which is incorporated herein in its entirety by reference.

### BACKGROUND

The disclosure relates to a semiconductor package and a method of fabricating the same, and more particularly, to a wafer level semiconductor package and a method of fabricating the same.

In semiconductor industries, technology has been advanced for increasing reliability in packaging and mounting small-sized integrated semiconductor chips. For example, demands for miniaturization have accelerated the development of small packages having sizes close to the sizes of integrated semiconductor chips, and demands for reliable mounting technology have spurred the development of packaging technology for efficiently packaging semiconductor chips and improving mechanical and electrical characteristics of the packaged semiconductor chips. Among semiconductor packaging techniques, a wafer level semiconductor package for packaging a chip at a wafer level is being developed while evolving in various forms.

### SUMMARY

According to certain embodiments, a method includes providing a package substrate; providing external connection terminals on a bottom surface of the package substrate; providing a first semiconductor chip on a top surface of the package substrate, the first semiconductor chip having a bottom surface facing the package substrate and a top surface opposite the bottom surface, and having a first conductive pad at the bottom surface; providing a second semiconductor chip on the first semiconductor chip, the second semiconductor chip having a bottom surface facing the top surface of the first semiconductor chip and a top surface opposite the bottom surface, and having a second conductive pad at the bottom surface; providing an insulating layer surrounding outer side surfaces of the first semiconductor chip; providing a first redistribution line extending from the first conductive pad to a region laterally outside of the first semiconductor chip, the first redistribution line disposed on the top surface of the package substrate and on the bottom surface of the first semiconductor chip, the first redistribution extending horizontally; and providing a second redistribution line extending from the second conductive pad to the region laterally outside of the first semiconductor chip, the second redistribution line including a first portion extending from the second conductive pad to the region laterally outside of the first semiconductor chip and a second portion extending between the first portion and between the first redistribution line, and extending horizontally and vertically between the first portion and between the first redistribution line.

In some embodiments, a method includes providing a first semiconductor chip and a first insulating layer surrounding lateral sides of the first semiconductor chip; providing a second semiconductor chip and a second insulating layer surrounding lateral sides of the second semiconductor chip; providing a third insulating layer below the first semiconductor chip and first insulating layer, so that the first semiconductor chip is between the third insulating layer and the second semiconductor chip, the third insulating layer forming a package substrate; providing a plurality of external connection terminals on the third insulating layer, such that the third insulating layer has a first surface facing the first semiconductor chip and a second surface facing the external connection terminals; providing a first redistribution line on the first surface of the third insulating layer and extending horizontally along the first surface of the third insulating layer, the first redistribution line contacting a first conductive pad of the first semiconductor chip; and providing a second redistribution line connected to a second conductive pad at a surface of the second semiconductor chip, the second redistribution line passing through the first insulating layer to contact the first redistribution line.

In some embodiments, a method includes: providing a second semiconductor chip surrounded by a second insulating layer; forming a first insulative structure on the second insulating layer, the first insulate structure protruding from a surface of the second insulating layer; conformally forming a second redistribution layer on the first insulative structure, the second insulating layer, and the second semiconductor chip, the redistribution layer contacting a conductive pad on the second semiconductor chip; mounting a first semiconductor chip on the second semiconductor chip; forming a first insulating layer to fill a space between the first insulative structure and the first semiconductor chip; and forming a first redistribution layer on the first semiconductor chip, the first insulating layer, and the first insulative structure, to contact the second redistribution layer.

In some embodiments, a stacked semiconductor package comprising: a base package comprising a fan-in region and a fan-out region surrounding the fan-in region, the fan-in region comprising a first chip and the fan-out region comprising a first insulating layer; at least one second chip on the first chip in the fan-in region; an insulative support structure on the first insulating layer in the fan-out region, the insulative support structure being spaced apart from the first chip and the second chip; a second insulating layer protecting the first chip and the second chip; a redistribution layer on one surface of the insulative support structure, the redistribution layer electrically connecting the first chip to the second chip; and a plurality of external connection terminals in the fan-in region and the fan-out region, the external connection terminals being electrically connected to the redistribution layer.

A stacked fan-out wafer level semiconductor package comprising: a base package comprising a first chip in a fan-in region and a first insulating layer in a fan-out region surrounding the fan-in region; a support member on the first insulating layer in the fan-out region; a first redistribution layer extending from an upper side of the first chip to an upper side of the support member; at least one second chip on the first chip; a second insulating layer surrounding the second chip and the support member, the second insulating layer exposing a surface of the second chip and a portion of an upper surface of the first redistribution layer; a second redistribution layer extending from an upper side of the second chip to the exposed portion of the upper surface of the first redistribution layer; a third insulating layer on the second chip, the second redistribution layer, the support member, and the second insulating layer; and a plurality of external connection terminals on the third insulating layer in the fan-in region and the fan-out region, the external connection terminals being electrically connected to the second redistribution layer.

In some embodiments, a stacked fan-out wafer level semiconductor package comprising: a base package comprising a first chip in a fan-in region and a first insulating layer in a fan-out region that surrounds the fan-in region, the first chip comprising a first chip pad on an upper side of the first chip; a support member on the first insulating layer in the fan-out region, the first insulating layer surrounding the first chip and being spaced apart from the first chip; a first redistribution layer extending from an upper side of the first chip pad of the first chip to an upper side of the support member; a second chip on the first chip, the second chip comprising a second chip pad on an upper side of the second chip; a second insulating layer surrounding the second chip and the support member, the second insulating layer exposing a surface of the second chip and an upper surface of the first redistribution layer; a second redistribution layer electrically connecting the second chip pad of the second chip to the exposed upper surface of the first redistribution layer; a third insulating layer on the second chip, the second redistribution layer, the support member, and the second insulating layer; and a plurality of external connection terminals on the third insulating layer in the fan-in region and the fan-out region, the external connection terminals being electrically connected to the second redistribution layer.

### BRIEF DESCRIPTION OF THE DRAWINGS

Embodiments of the inventive concept will be more clearly understood from the following detailed description taken in conjunction with the accompanying drawings in which:

FIGS. 1A and 1B are plan views of a main portion of a stacked fan-out wafer level semiconductor package according to an exemplary embodiment;

FIGS. 2A and 2B are sectional views of the main portion of the stacked fan-out wafer level semiconductor package of FIGS. 1A and 1B, taken along a line II-IF of FIGS. 1A and 1B, according to an exemplary embodiment;

FIG. 3 is a sectional view of an comparative embodiment for comparison with the embodiment of FIGS. 2A and 2B, according to an exemplary embodiment;

FIG. 4 is a plan view of a main portion of a stacked fan-out wafer level semiconductor package according to an exemplary embodiment;

FIGS. 5A and 5B are sectional views of the main portion of the stacked fan-out wafer level semiconductor package of FIG. 4, taken along a line V-V of FIG. 4, according to an exemplary embodiment;

FIG. 6 is a sectional view of a main portion of a stacked fan-out wafer level semiconductor package according to an exemplary embodiment;

FIG. 7 is a sectional view of a main portion of a stacked fan-out wafer level semiconductor package according to an exemplary embodiment;

FIGS. 8A and 8B are sectional views of a main portion of a stacked fan-out wafer level semiconductor package according to an exemplary embodiment;

FIG. 9 is a sectional view of a main portion of a stacked fan-out wafer level semiconductor package according to an exemplary embodiment;

FIG. 10 is a sectional view of a main portion of a stacked fan-out wafer level semiconductor package according to an exemplary embodiment;

FIGS. 11 to 21 are diagrams for explaining a method of fabricating a stacked fan-out wafer level semiconductor package according to an exemplary embodiment;

FIGS. 22 and 23 show a flow chart for explaining a method of fabricating a stacked fan-out wafer level semiconductor package according to an exemplary embodiment;

FIG. 24 is a schematic plan view of a semiconductor module including a stacked fan-out wafer level semiconductor package according to an exemplary embodiment;

FIG. 25 is a schematic diagram of a card including a stacked fan-out wafer level semiconductor package according to an exemplary embodiment;

FIG. 26 is a schematic block diagram of an electronic circuit board including a stacked fan-out wafer level semiconductor package according to an exemplary embodiment;

FIG. 27 is a schematic block diagram of an electronic system including a stacked fan-out wafer level semiconductor package according to an exemplary embodiment;

FIG. 28 is a schematic diagram of an electronic system including a stacked fan-out wafer level semiconductor package according to an exemplary embodiment; and

FIG. 29 is a schematic perspective view of an electronic device including a stacked fan-out wafer level semiconductor package according to an exemplary embodiment.

### DETAILED DESCRIPTION

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, the size and relative sizes of layers and regions may be exaggerated for clarity. Like numbers refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

The terminology used herein is for the purpose of describing particular embodiments only and is not intended to be limiting of the invention. As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present. Other words used to describe the relationship between elements should be interpreted in a like fashion (e.g., “between” versus “directly between,” “adjacent” versus “directly adjacent,” etc.).

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures may have schematic properties, and shapes of regions shown in figures may exemplify specific shapes of regions of elements to which aspects of the invention are not limited.

It should be noted that steps related to the methods disclosed may be described in one order, but may occur in a different order. The context and specific descriptions in the specification will inform how the orders of different steps may or should occur.

Although the figures described herein may be referred to using language such as “one embodiment,” or “certain embodiments,” these figures, and their corresponding descriptions are not intended to be mutually exclusive from other figures or descriptions, unless the context so indicates. Therefore, certain aspects from certain figures may be the same as certain features in other figures, and/or certain figures may be different representations or different portions of a particular exemplary embodiment.

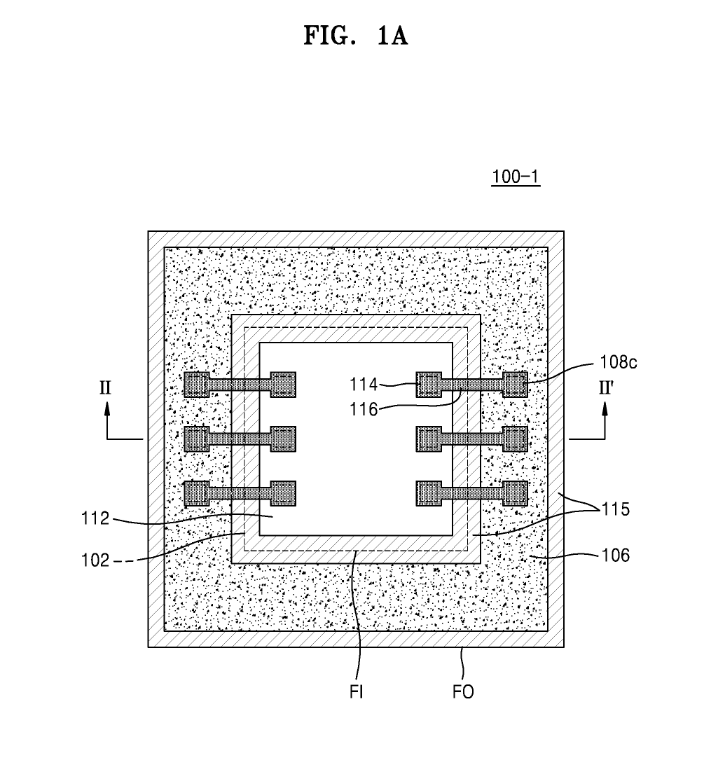

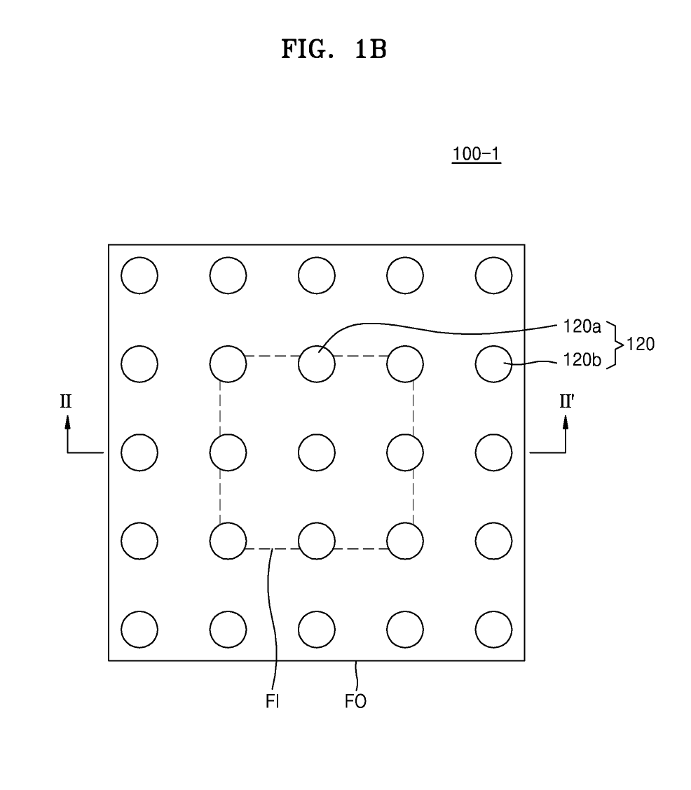

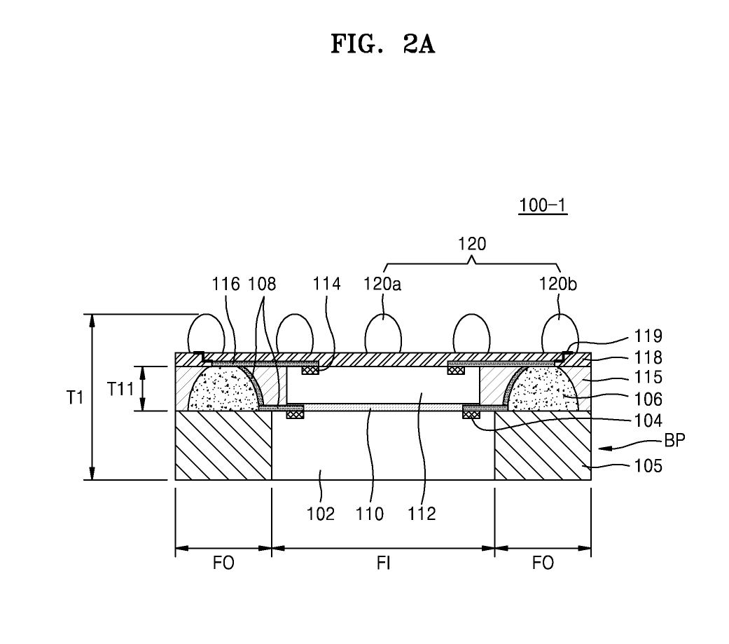

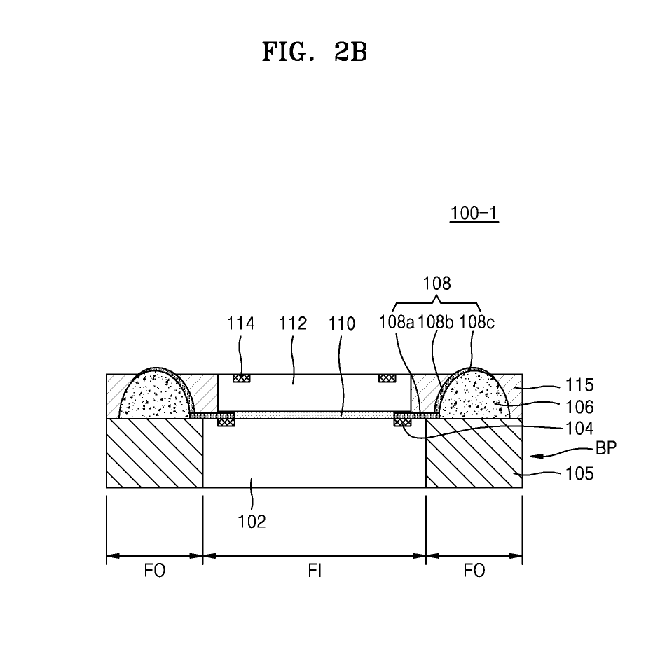

FIGS. 1A and 1B are plan views of a main portion of a stacked fan-out wafer level semiconductor package according to an exemplary embodiment, and FIGS. 2A and 2B are sectional views of the main portion of the stacked fan-out wafer level semiconductor package of FIGS. 1A and 1B, taken along a line II-II′ of FIGS. 1A and 1B.

Specifically, FIG. 1A is a plan view of a stacked fan-out wafer level semiconductor package 100-1, in which an external connection terminal 120 of FIG. 1B is not shown for convenience, and FIG. 1B is a plan view of the stacked fan-out wafer level semiconductor package 100-1, in which only the external connection terminal is shown.

FIG. 2A is a sectional view of the main portion, which is shown as including the external connection terminal 120 of FIG. 1B, taken along the line II-II′ of FIGS. 1A and 1B, and FIG. 2B is a sectional view of the main portion, which is shown for describing a first redistribution layer 108 in detail, taken along the line II-II′ of FIGS. 1A and 1B.

The stacked fan-out wafer level semiconductor package 100-1 may include a base package BP including a fan-in region FI, which includes a first chip 102, and a first insulating layer 105 in a fan-out region FO surrounding the fan-in region FI. The first chip 102 is arranged in the fan-in region FI of the base package BP. In one embodiment, the first chip 102 may be a logic chip (or a control chip). The first insulating layer 105 is formed in the fan-out region FO of the base package BP. The first insulating layer 105 may be a molding layer which molds the first chip 102. The molding layer may be formed, for example, of a polymer layer such as a resin. The molding layer may be formed of, for example, an epoxy molding compound (EMC). The first chip 102 may include a plurality of first chip pads 104.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may generally have a planar surface area (often larger than a corresponding surface area of the internal wiring to which they are connected) to promote connection to a further terminal, such as a bump or solder ball, and/or an external wiring.

As used herein, a semiconductor package may refer to a semiconductor device having one or more chips stacked on a package substrate. A semiconductor package may also refer to a plurality of stacked packages, such as a package-on-package device. The term “semiconductor device” may be used generally to refer to one of these packages, whether a single package or a package-on-package device, and may also be used to refer to devices such as single semiconductor chips, e.g., formed on a die from as wafer.

In FIGS. 1A, 2A, and 2B, the first chip pads 104 may be edge pads in a portion near an edge of the first chip 102. A second chip 112 is arranged on the first chip 102 in the fan-in region FI.

In this exemplary embodiment, the second chip 112 is stacked on and attached to the first chip 102 in the fan-in region FI via an adhesive layer 110. The second chip 112 may be, for example, a memory chip. The adhesive layer 110 may be formed of a non-conductive film (NCF), an anisotropic conductive film (ACF), a UV film, an instantaneous adhesive, a thermosetting adhesive, a laser-curable adhesive, an ultrasonic wave-curable adhesive, a non-conductive paste (NCP), or the like.

In FIGS. 1A, 2A, and 2B, although the second chip 112 is shown as having a smaller size than the first chip 102 since the second chip 112 is arranged in the first chip 102, the second chip 112 may have a larger size than the first chip 102. For example, in some embodiments, the second chip 112 may also occupy the fan-out region FO around the fan-in region FI. Although not shown in FIG. 1A, in some embodiments, the redistribution lines 116, described in greater detail below, have a fan shape, in which they are closer together at a location vertically overlapping the first and/or second chip that they are connected to, and get wider apart from each other as they extend into the region outside the first and/or second chip and that does not overlap the first and/or second chip. The region overlapping the one or more chips may be described as the fan-in region, and the region outside one or all of the chips may be described as the fan-out region.

In the exemplary embodiment of FIG. 1A, although the second chip 112 is shown as being arranged in the first chip 102, in an alternative embodiment, the second chip 112 may have a rectangular shape, and thus may be arranged beyond the first chip 102 in terms of a width or length direction of the second chip 112.

As shown in FIGS. 1A, 2A, and 2B, the second chip 112 may be of a different kind from the first chip 102. For example, the first chip 102 may be a logic chip (or a control chip) and the second chip 112 may be a memory chip. In some embodiments, the second chip 112 may be of a same type as the first chip 102. The second chip 112 may include a plurality of second chip pads 114. In FIGS. 1A, 2A, and 2B, the second chip pads 114 may be edge pads in a portion near an edge of the second chip 112.

A support member 106 is arranged in the fan-out region FO while being apart from the first chip 102 and the second chip 112. The support member 106 is formed on the first insulating layer 105 in the fan-out region FO. The support member 106 may be a dam member which is formed on the first insulating layer 105 and continuously surrounds the first chip 102 and the second chip 112.

In one embodiment, the support member 106 is formed of a non-conductive material. The support member 106 may include, for example, a polymer layer. In some embodiments, as shown in FIG. 2A, an uppermost surface of the support member 106 may be vertically at the same level as an uppermost surface of the second chip 112. In some embodiments, as shown in FIG. 2B, the uppermost surface of the support member 106 may be vertically at a higher level than the uppermost surface of the second chip 112. As shown in FIGS. 2A and 2B, the support member 106 may have a semi-elliptical cross section, but is not limited thereto. The support member 106 may have any desired geometrical configurations. In some embodiments, for example, the support member 106 may have a quadrangular (e.g., rectangular or square) cross section or another type of angled cross section.

In some embodiments, the first redistribution layer 108 extends from an upper side of the first chip 102 to an upper side of the support member 106. For example, the first redistribution layer 108 may include aluminum, copper, or the like. As shown in FIG. 2B, the first redistribution layer 108 may include a first sub-redistribution layer 108a on the first chip pad 104, the first chip 102, and the first insulating layer 105, a second sub-redistribution layer 108b on one side surface of the support member 106, and a third sub-redistribution layer 108c on an upper surface of the support member 106. The first redistribution layer 108 may be referred to generally as a first line, or redistribution line. It may have a linear shape, that may be flat along the surface of the first chip 102 and first insulating layer 105, and then may bend away from the first insulating layer 105 to conformally follow the shape of the support member 106, thereby forming an overall bent shape bent in a vertical direction.

The stacked fan-out wafer level semiconductor package 100-1 may include a second insulating layer 115 protecting the first chip 102 and the second chip 112. The second insulating layer 115 surrounds the second chip 112 and the support member 106, at least around their side surfaces. The second insulating layer 115 may be a coating layer surrounding the second chip 112 and the support member 106. For example, the second insulating layer 115 may be formed of an oxide layer, a nitride layer, a polymer layer, or combinations thereof. The second insulating layer 115 combined with the support member 106 may together be referred to as an insulating layer, as in some embodiments, they are both formed of an insulating material.

As shown in FIG. 2B, the second insulating layer 115 is formed around the second chip 112 and the support member 106 such that the surface of the second chip 112 and a portion of an upper surface of the first redistribution layer 108, for example, the third sub-redistribution layer 108c are exposed with respect to the second insulating layer 115. As shown in FIG. 2B, the second insulating layer 115 surrounds the second chip 112 and the support member 106 while exposing the surface of the second chip 112 and the portion of the upper surface of the first redistribution layer 108, for example, the third sub-redistribution layer 108c.

A second redistribution layer 116 extends from an upper side of the second chip 112 to an upper side of the first redistribution layer 108 that is exposed. The second redistribution layer 116 is formed on surfaces of the second chip pad 114, the second chip 112, the second insulating layer 115, and the first redistribution layer 108 that is exposed. The second redistribution layer 116, which may also be referred to as a second line, or redistribution line, electrically connects the second chip pad 114 of the second chip 112 to the first redistribution layer 108 that is exposed. The second redistribution layer 116 may therefore contact both the second chip pad 114 and a portion of the first redistribution layer 108 (e.g., the third sub-redistribution layer 108c. For example, the second redistribution layer 116 may include aluminum, copper, or the like. The stacked fan-out wafer level semiconductor package 100-1 allows the first chip 102 and the second chip 112 to be electrically connected to each other by the redistribution layers including the first redistribution layer 108 and the second redistribution layer 116.

As shown in FIG. 2A, the stacked fan-out wafer level semiconductor package 100-1 includes a third insulating layer 118 which is formed on the second chip 112, the second redistribution layer 116, the support member 106, and the second insulating layer 115. The third insulating layer 118 may be formed of an oxide layer, a nitride layer, a polymer layer, or combinations thereof. The third insulating layer 118 may form a bottom, or base layer, of the semiconductor package 100-1.

As shown in FIG. 2A, the external connection terminal 120, which is electrically connected to the redistribution layers 108, 116 through an internal wiring layer 119 in the third insulating layer 118, is formed on the third insulating layer 118 in the fan-in region FI and the fan-out region FO. The external connection terminal 120 may be formed, for example, of copper (Cu), aluminum (Al), gold (Au), a solder, or the like. If formed of a solder, the external connection terminal 120 may be referred to as a solder ball or solder bump.

The external connection terminal 120 may be electrically connected to the first redistribution layer 108 through the internal wiring layer 119 and the second redistribution layer 116. The external connection terminal 120 may include a first external connection terminal 120a in the fan-in region FI and a second external connection terminal 120b in the fan-out region FO.

As such, the stacked fan-out wafer level semiconductor package 100-1 includes the external connection terminal 120 which is formed even in the fan-out region FO that is larger in size (area) than the chips 102, 112, thereby realizing a semiconductor package that is advantageous for high performance and high speed signal processing. It should be noted that although certain explanations herein describe features with respect to only one element (e.g., an external connection terminal 120, or a redistribution line), it should be evident from the drawings that a plurality of such elements are included in the various embodiments shown in the various figures.

The stacked fan-out wafer level semiconductor package 100-1 allows the first chip 102 and the second chip 112 to be electrically connected to each other through the support member 106 and the redistribution layers 108, 116, thereby realizing a semiconductor package to a thin thickness T1. Since the stacked fan-out wafer level semiconductor package 100-1 allows a thickness T11 of the support member 106 to be set to correspond to a thickness of the second chip 112 without a solder connector, the thickness T1 of the package can be reduced.

In addition, the stacked fan-out wafer level semiconductor package 100-1 allows the second chip 112 to be directly reliably stacked on the first chip 102 (e.g., directly stacked through the adhesive 110), thereby exhibiting a high fabrication yield and a reduced fabrication cost.

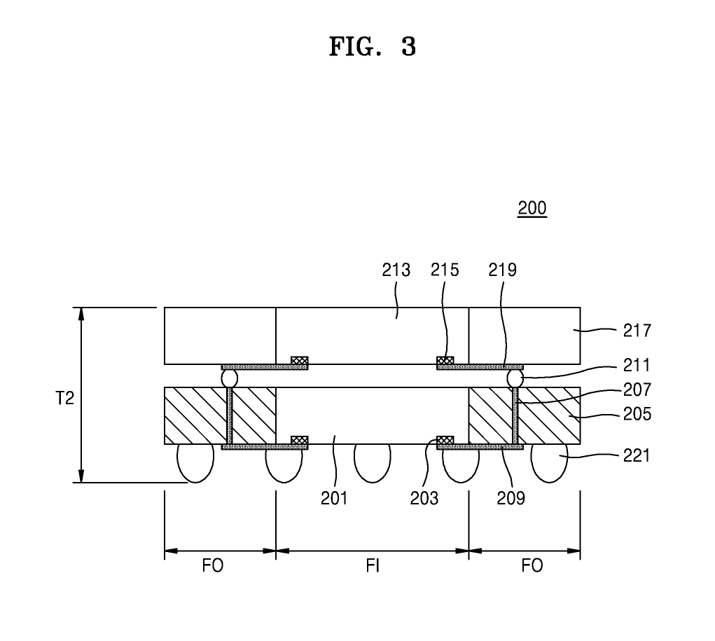

FIG. 3 is a sectional view of a comparative embodiment for comparison with the embodiment of FIGS. 2A and 2B.

Specifically, a stacked fan-out wafer level semiconductor package 200 of FIG. 3 according to the comparative embodiment includes a first chip 201 in the fan-in region FI, and a first insulating layer 205 in the fan-out region FO at both sides of the first chip 201.

A first chip pad 203 is formed on a lower surface of the first chip 201, and electrically connected to a first redistribution layer 209. The first redistribution layer 209 is connected to a through-via 207 inside the first insulating layer 205. The first redistribution layer 209 is connected to an external connection terminal 221.

In the stacked fan-out wafer level semiconductor package 200 according to the comparative embodiment, the first chip 201 and a second chip 213, which is connected to the first chip 201 through a solder connector 211 on the first insulating layer 205, are mounted. The second chip 213 is mounted on an upper side of the fan-in region FI, and a second insulating layer 217 is formed on an upper side of the fan-out region FO at both sides of the second chip 213.

A second chip pad 215 is formed on a lower surface of the second chip 213, and connected to a second redistribution layer 219 on the lower surface of the second chip 213 and on a lower surface of the second insulating layer 217. The second redistribution layer 219 may be connected to the first chip 201 through the solder connector 211, the though-via 207, and the first redistribution layer 209.

Hereinafter, the stacked fan-out wafer level semiconductor package 100-1 of FIGS. 2A and 2B will be compared with the stacked fan-out wafer level semiconductor package 200 of FIG. 3 according to the comparative embodiment.

As described above, since the stacked fan-out wafer level semiconductor package 100-1 of FIGS. 2A and 2B does not include the solder connector 211, the thickness T1 of the semiconductor package 100-1 can be less than a thickness T2 of the stacked fan-out wafer level semiconductor package 200 of FIG. 3.

Since the stacked fan-out wafer level semiconductor package 100-1 of FIGS. 2A and 2B allows the second chip 112 to be directly stacked on the first chip 102 (e.g., directly stacked through the adhesive 110) without use of the through-via 207, the semiconductor package 100-1 can exhibit a higher fabrication yield and a lower fabrication cost than the stacked fan-out wafer level semiconductor package 200 of FIG. 3.

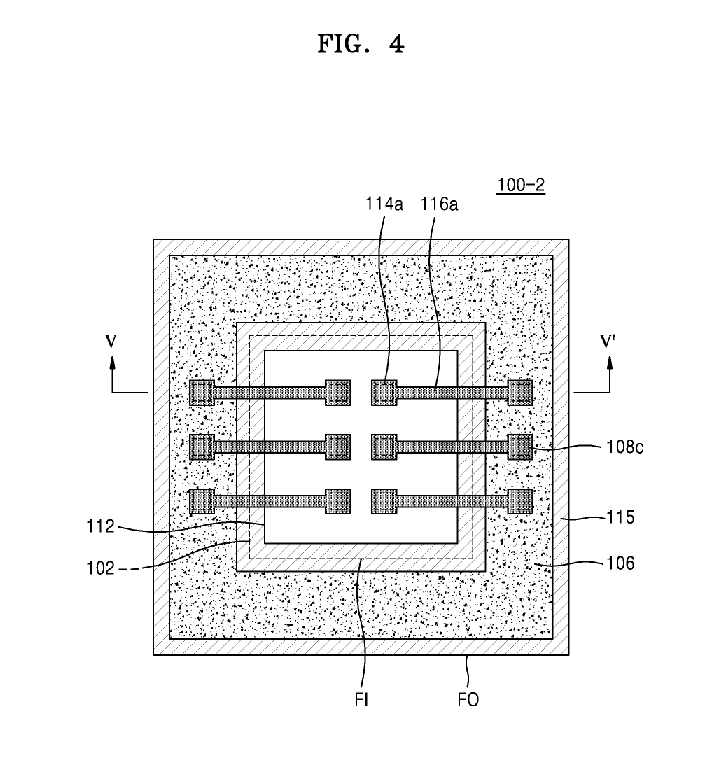

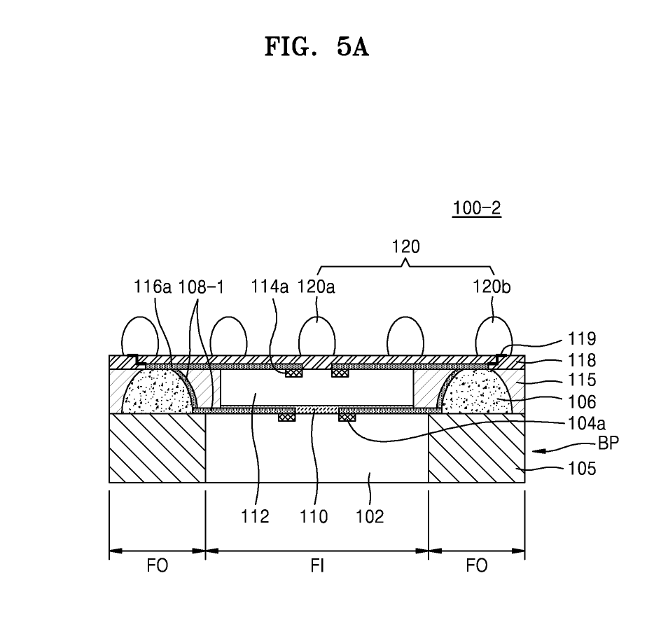

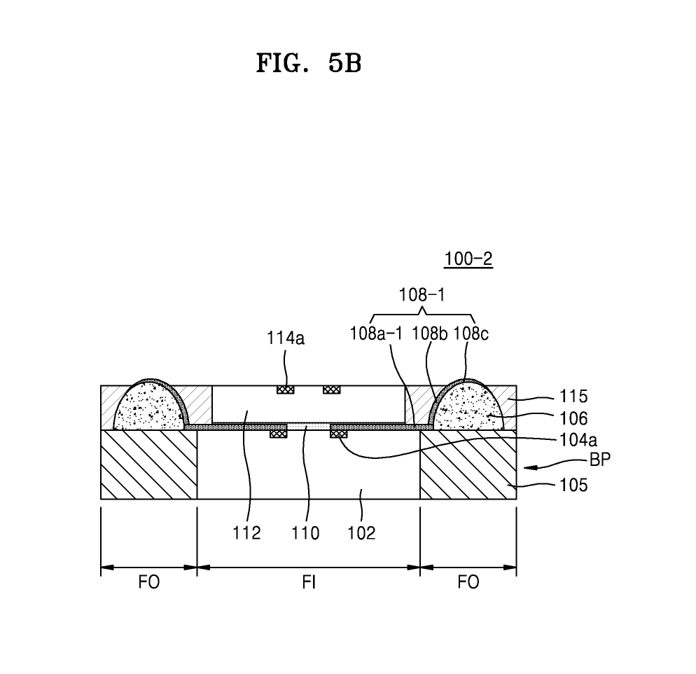

FIG. 4 is a plan view of a main portion of a stacked fan-out wafer level semiconductor package according to an embodiment, and FIGS. 5A and 5B are sectional views of the main portion of the stacked fan-out wafer level semiconductor package of FIG. 4, taken along a line V-V of FIG. 4.

Specifically, FIG. 4 is a diagram of a stacked fan-out wafer level semiconductor package 100-2, in which the external connection terminal 120 is not shown for convenience. FIG. 5A is a sectional view of the stacked fan-out wafer level semiconductor package 100-2, which is shown as including the external connection terminal 120, taken along the line V-V of FIG. 4, and FIG. 5B is a sectional view of the stacked fan-out wafer level semiconductor package 100-2, which is shown for describing a first redistribution layer 108-1 in detail, taken along the line V-V of FIG. 4.

The stacked fan-out wafer level semiconductor package 100-2 may be almost the same as the stacked fan-out wafer level semiconductor package 100-1 of FIGS. 1A, 1B, 2A, and 2B except that a first chip pad 104a and a second chip pad 114a are respectively center pads in central portions of the first chip 102 and the second chip 112. In descriptions with reference to FIGS. 4, 5A, and 5B, the same reference numerals as in FIGS. 1A, 1B, 2A, and 2B denote the same components, and overlapping portions will be briefly described or omitted for convenience.

The stacked fan-out wafer level semiconductor package 100-2 may include the base package BP including the fan-in region FI, which includes the first chip 102, and the first insulating layer 105 in the fan-out region FO surrounding the fan-in region FI.

The first chip 102 may include a plurality of first chip pads 104a. In FIGS. 5A and 5B, the first chip pads 104a may be center pads in the central portion of the first chip 102. The second chip 112 is stacked on and attached to the first chip 102 in the fan-in region FI via the adhesive layer 110. The second chip 112 may include a plurality of second chip pads 114a. In FIGS. 4, 5A, and 5B, the second chip pads 114a may be center pads in the central portion of the second chip 112.

The support member 106 is arranged in the fan-out region FO while being apart from the first chip 102 and the second chip 112. The first redistribution layer 108-1 extends from the upper side of the first chip 102 to the upper side of the support member 106. As shown in FIG. 5B, the first redistribution layer 108-1 may include a first sub-redistribution layer 108a-1 on the first chip pad 104a, the first chip 102, and the first insulating layer 105, the second sub-redistribution layer 108b on the one side surface of the support member 106, and the third sub-redistribution layer 108c on the upper surface of the support member 106.

The stacked fan-out wafer level semiconductor package 100-2 may include the second insulating layer 115 protecting the first chip 102 and the second chip 112. As shown in FIG. 5B, the second insulating layer 115 is formed around the second chip 112 and the support member 106 such that the surface of the second chip 112 and the upper (uppermost) surface of the first redistribution layer 108, that is, the third sub-redistribution layer 108c are exposed.

A second redistribution layer 116a extends from the upper side of the second chip 112 to an upper side of the first redistribution layer 108-1 that is exposed. The second redistribution layer 116a electrically connects the second chip pad 114a of the second chip 112 to the first redistribution layer 108-1 that is exposed. The stacked fan-out wafer level semiconductor package 100-2 allows the first chip 102 and the second chip 112 to be electrically connected to each other by redistribution layers including the first redistribution layer 108-1 and the second redistribution layer 116a.

As shown in FIG. 5A, the stacked fan-out wafer level semiconductor package 100-2 includes the third insulating layer 118 which is formed on the second chip 112, the second redistribution layer 116a, the support member 106, and the second insulating layer 115. As shown in FIGS. 4 and 5A, the external connection terminal 120, which is electrically connected to the redistribution layers 108-1, 116a through the internal wiring layer 119, is formed on the third insulating layer 118 in the fan-in region FI and the fan-out region FO. The external connection terminal 120 may include the first external connection terminal 120a in the fan-in region FI and the second external connection terminal 120b in the fan-out region FO.

As such, even though including the first chip pad 104a and the second chip pad 114a which are respectively the center pads in the central portions of the first chip 102 and the second chip 112, the stacked fan-out wafer level semiconductor package 100-2 can provide the same effects as the stacked fan-out wafer level semiconductor package 100-1.

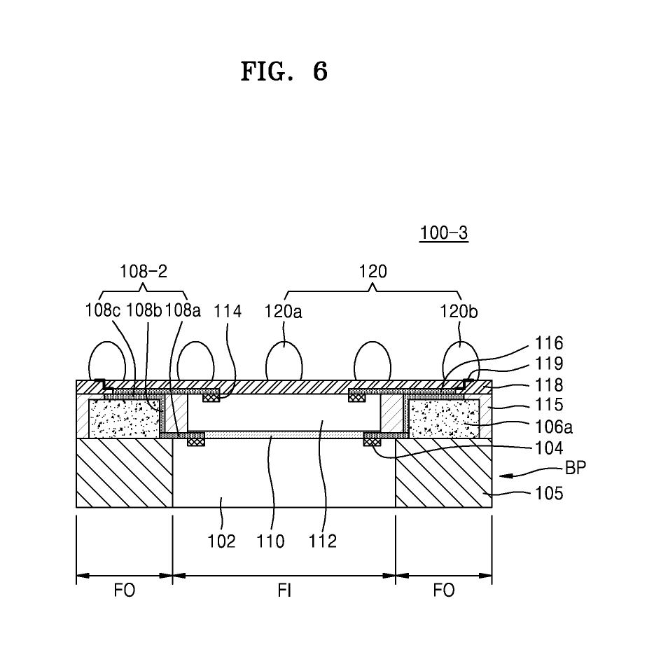

FIG. 6 is a sectional view of a main portion of a stacked fan-out wafer level semiconductor package according to an embodiment.

Specifically, a stacked fan-out wafer level semiconductor package 100-3 may be almost the same as the stacked fan-out wafer level semiconductor package 100-1 of FIGS. 2A and 2B except that a support member 106a has a rectangular cross section. In descriptions with reference to FIG. 6, the same reference numerals as in FIGS. 2A and 2B denote the same components, and overlapping portions will be briefly described or omitted for convenience.

The stacked fan-out wafer level semiconductor package 100-3 may include the base package BP including the fan-in region FI, which includes the first chip 102, and the first insulating layer 105 in the fan-out region FO surrounding the fan-in region FI.

The first chip 102 may include the plurality of first chip pads 104. The second chip 112 is stacked on and attached to the first chip 102 in the fan-in region FI via the adhesive layer 110. The support member 106a is arranged in the fan-out region FO while being apart from the first chip 102 and the second chip 112. The support member 106a may be a support member having a rectangular cross section.

A first redistribution layer 108-2 extends from the upper side of the first chip 102 to an upper side of the support member 106a. The first redistribution layer 108-2 may include the first sub-redistribution layer 108a on the first chip pad 104, the first chip 102, and the first insulating layer 105, the second sub-redistribution layer 108b on one side surface of the support member 106a, and the third sub-redistribution layer 108c on an upper surface of the support member 106a.

The stacked fan-out wafer level semiconductor package 100-3 may include the second insulating layer 115 protecting the first chip 102 and the second chip 112. The second redistribution layer 116 extends from the upper side of the second chip 112 to an upper side of the first redistribution layer 108-2 that is exposed. The first chip 102 and the second chip 112 are electrically connected to each other by the redistribution layers including the first redistribution layer 108-2 and the second redistribution layer 116.

The stacked fan-out wafer level semiconductor package 100-3 includes the third insulating layer 118 which is formed on the second chip 112, the second redistribution layer 116, the support member 106a, and the second insulating layer 115. The external connection terminal 120, which is electrically connected to the redistribution layers 108-2, 116 through the internal wiring layer 119, is formed on the third insulating layer 118 in the fan-in region FI and the fan-out region FO. The external connection terminal 120 may include the first external connection terminal 120a in the fan-in region FI and the second external connection terminal 120b in the fan-out region FO.

As such, even though including the support member 106a having a rectangular cross section, the stacked fan-out wafer level semiconductor package 100-3 can provide the same effects as the stacked fan-out wafer level semiconductor package 100-1.

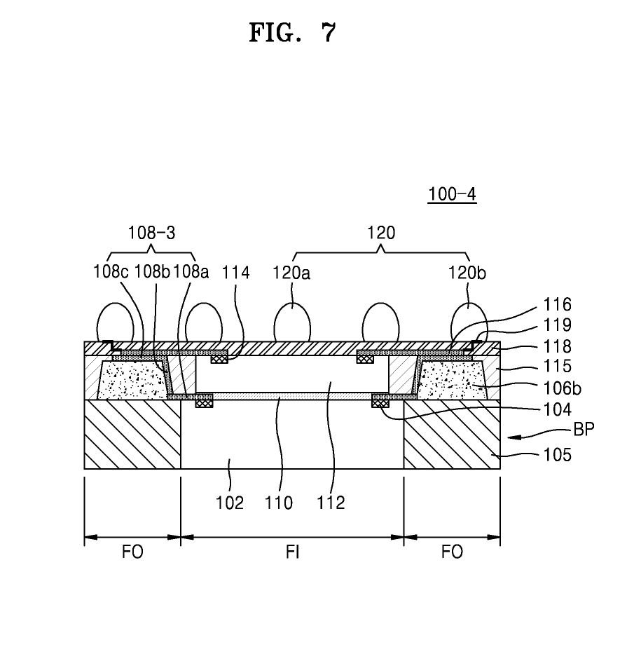

FIG. 7 is a sectional view of a main portion of a stacked fan-out wafer level semiconductor package according to an exemplary embodiment.

Specifically, a stacked fan-out wafer level semiconductor package 100-4 may be almost the same as the stacked fan-out wafer level semiconductor package 100-1 of FIGS. 2A and 2B except that a support member 106b has a trapezoidal cross section. In descriptions with reference to FIG. 7, the same reference numerals as in FIGS. 2A and 2B denote the same components, and overlapping portions will be briefly described or omitted for convenience.

The stacked fan-out wafer level semiconductor package 100-4 may include the base package BP including the fan-in region FI, which includes the first chip 102, and the first insulating layer 105 in the fan-out region FO surrounding the fan-in region FI.

The first chip 102 may include the plurality of first chip pads 104. The second chip 112 is stacked on and attached to the first chip 102 in the fan-in region FI via the adhesive layer 110. The support member 106b is arranged in the fan-out region FO while being apart from the first chip 102 and the second chip 112. The support member 106b may be a support member having a trapezoidal cross section.

A first redistribution layer 108-3 extends from the upper side of the first chip 102 to an upper side of the support member 106b. The first redistribution layer 108-3 may include the first sub-redistribution layer 108a on the first chip pad 104, the first chip 102, and the first insulating layer 105, the second sub-redistribution layer 108b on one side surface of the support member 106b, and the third sub-redistribution layer 108c on an upper surface of the support member 106b.

The stacked fan-out wafer level semiconductor package 100-4 may include the second insulating layer 115 protecting the first chip 102 and the second chip 112. The second redistribution layer 116 extends from the upper side of the second chip 112 to an upper side of the first redistribution layer 108-3 that is exposed. The first chip 102 and the second chip 112 are electrically connected to each other by redistribution layers including the first redistribution layer 108-3 and the second redistribution layer 116.

The stacked fan-out wafer level semiconductor package 100-4 includes the third insulating layer 118 which is formed on the second chip 112, the second redistribution layer 116, the support member 106b, and the second insulating layer 115. The external connection terminal 120, which is electrically connected to the redistribution layers 108-3, 116 through the internal wiring layer 119, is formed on the third insulating layer 118 in the fan-in region FI and the fan-out region FO. The external connection terminal 120 may include the first external connection terminal 120a in the fan-in region FI and the second external connection terminal 120b in the fan-out region FO.

As such, even though including the support member 106b having a trapezoidal cross section, the stacked fan-out wafer level semiconductor package 100-4 can provide the same effects as the stacked fan-out wafer level semiconductor package 100-1. Although the support members 106a, 106b are illustrated as having a rectangular or trapezoidal cross section in FIGS. 6 and 7, the stacked fan-out wafer level semiconductor package according to the inventive concept may include a support member having a quadrangular cross section, for example, a parallelogrammic cross section, a rhombus-shaped cross section, a square cross section, or the like.

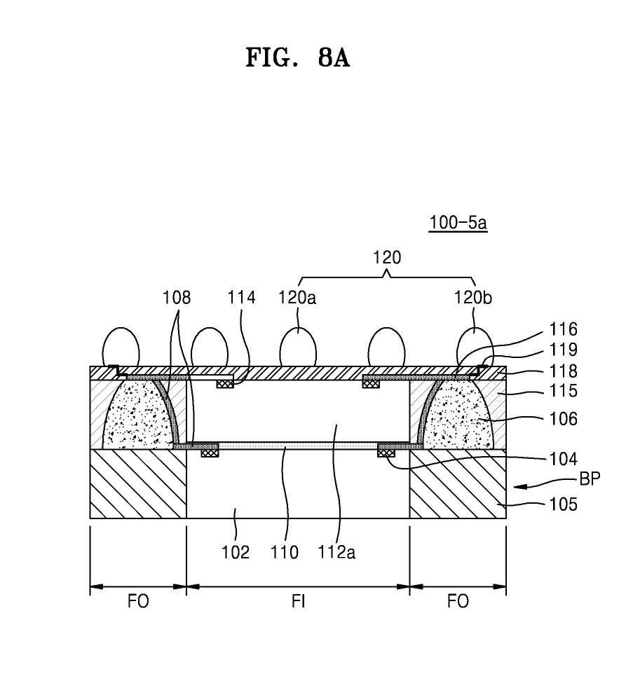

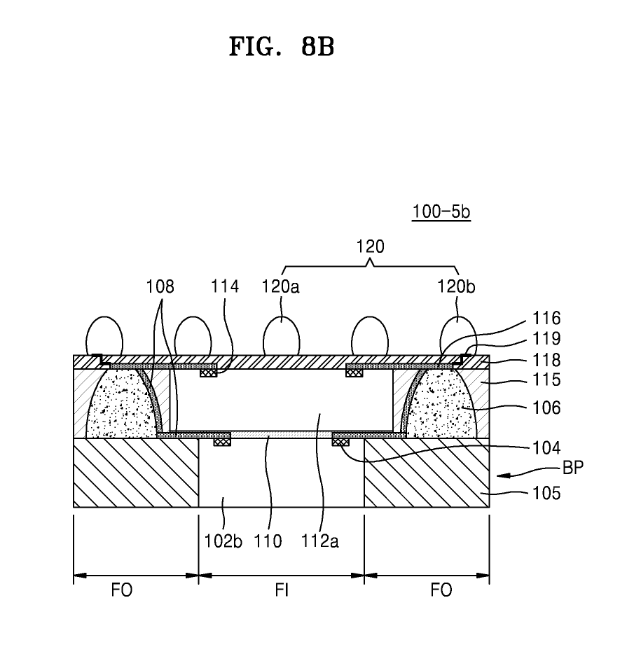

FIGS. 8A and 8B are sectional views of a main portion of a stacked fan-out wafer level semiconductor package according to an embodiment.

Specifically, stacked fan-out wafer level semiconductor packages 100-5a, 100-5b may be the same as the stacked fan-out wafer level semiconductor package 100-1 of FIGS. 2A and 2B except that sizes or kinds of first chips 102, 102b are different from those of second chip 112a. In the stacked fan-out wafer level semiconductor package 100-5a of FIG. 8A, the second chip 112a may be of the same type as the first chip 102, and thus have the same size as that of the first chip 102.

In the stacked fan-out wafer level semiconductor package 100-5b of FIG. 8B, the second chip 112a may be of a different type from the first chip 102b, and thus have a different size from that of the first chip 102b. In addition, the second chip 112a of the stacked fan-out wafer level semiconductor package 100-5b of FIG. 8B may have a larger size than that of the first chip 102b, and may also occupy the first insulating layer 105. In descriptions with reference to FIGS. 8A and 8B, the same reference numerals as in FIGS. 2A and 2B denote the same components, and overlapping portions will be briefly described or omitted for convenience.

The stacked fan-out wafer level semiconductor packages 100-5a, 1005b may include the base package BP including the fan-in region FI, which includes the first chip 102 or 102b, and the first insulating layer 105 in the fan-out region FO surrounding the fan-in region FI. The first chips 102 or 102b may be a logic chip (or a control chip). The first chip 102 or 102b may include the plurality of first chip pads 104.

The second chip 112a is stacked on and attached to the first chip 102 or 102b in the fan-in region FI via the adhesive layer 110. In FIG. 8B, since the size of the first chip 102b is less than that of the second chip 112a, the second chip 112a may occupy the fan-out region FO. The second chip 112a may have a size that is less than the size of the first chip 102b, as needed.

The second chip 112a may be of the same type as or of a different type from the first chip 102 or 102b. The second chip 112a may be a logic chip (or a control chip). The second chip 112a may have a size that is the same as or different from the size of the first chip 102 or 102b. The second chip 112a may include the second chip pads 114.

The support member 106 is arranged in the fan-out region FO while being apart from the first chip 102 or 102b and the second chip 112a. The first redistribution layer 108 extends from the upper side of the first chip 102 or 102b to the upper side of the support member 106.

The stacked fan-out wafer level semiconductor packages 100-5a, 100-5b may include the second insulating layer 115 protecting the first chip 102 or 102b and the second chip 112a. The second redistribution layer 116 extends from an upper side of the second chip 112a to the upper side of the first redistribution layer 108. The first chip 102 or 102b and the second chip 112a are electrically connected to each other by the redistribution layers including the first redistribution layer 108 and the second redistribution layer 116.

The third insulating layer 118 is formed on the second chip 112a, the second redistribution layer 116, the support member 106, and the second insulating layer 115. The external connection terminal 120, which is electrically connected to the redistribution layers 108, 116 through the internal wiring layer 119, is formed on the third insulating layer 118 in the fan-in region FI and the fan-out region FO. The external connection terminal 120 may include the first external connection terminal 120a in the fan-in region FI and the second external connection terminal 120b in the fan-out region FO.

As such, even though including the first chip 102 or 102b and the second chip 112a which are of the same kind or of a different kind, the stacked fan-out wafer level semiconductor packages 100-5a, 1005b can provide the same effects as the stacked fan-out wafer level semiconductor package 100-1.

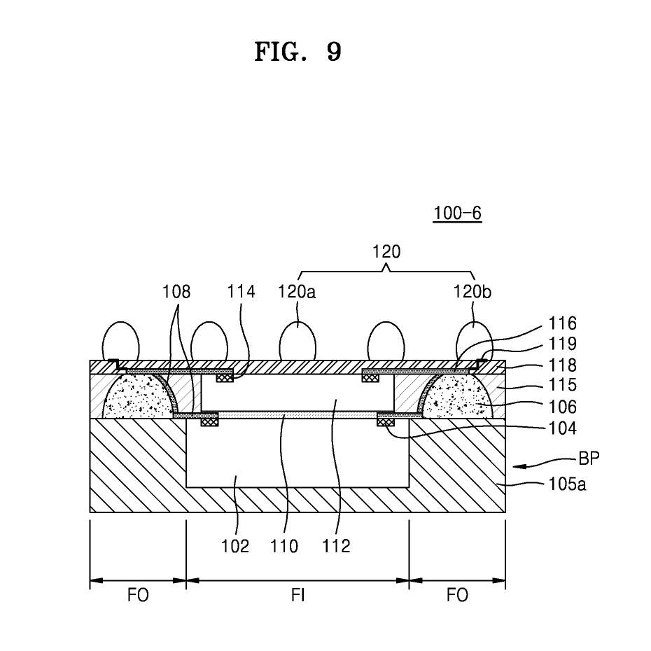

FIG. 9 is a sectional view of a main portion of a stacked fan-out wafer level semiconductor package according to an embodiment.

Specifically, a stacked fan-out wafer level semiconductor package 100-6 may be almost the same as the stacked fan-out wafer level semiconductor package 100-1 of FIGS. 2A and 2B except that a first insulating layer 105a is formed on a lower side of the first chip 102. In descriptions with reference to FIG. 9, the same reference numerals as in FIGS. 2A and 2B denote the same components, and overlapping portions will be briefly described or omitted for convenience.

The stacked fan-out wafer level semiconductor package 100-6 may include the base package BP including the fan-in region FI, which includes the first chip 102, and the first insulating layer 105a in the fan-out region FO surrounding the fan-in region FI. In addition, in the base package BP, the first insulating layer 105a is further formed on the lower side of the first chip 102 in the fan-in region FI, thereby protecting the first chip 102. The first chip 102 may include the plurality of first chip pads 104.

The second chip 112 is stacked on and attached to the first chip 102 in the fan-in region FI via the adhesive layer 110. The second chip 112 may include the second chip pads 114. The support member 106 is arranged in the fan-out region FO while being apart from the first chip 102 and the second chip 112. The first redistribution layer 108 extends from the upper side of the first chip 102 to the upper side of the support member 106.

The stacked fan-out wafer level semiconductor package 100-6 may include the second insulating layer 115 protecting the first chip 102 and the second chip 112. The second redistribution layer 116 extends from the upper side of the second chip 112 to the upper side of the first redistribution layer 108. The first chip 102 and the second chip 112 are electrically connected to each other by the redistribution layers including the first redistribution layer 108 and the second redistribution layer 116.

The third insulating layer 118 is formed on the second chip 112, the second redistribution layer 116, the support member 106, and the second insulating layer 115. The external connection terminal 120, which is electrically connected to the redistribution layers 108, 116 through the internal wiring layer 119, is formed on the third insulating layer 118 in the fan-in region FI and the fan-out region FO. The external connection terminal 120 may include the first external connection terminal 120a in the fan-in region FI and the second external connection terminal 120b in the fan-out region FO.

As such, even though further including the first insulating layer 105a on the lower side of the first chip 102, the stacked fan-out wafer level semiconductor package 100-6 can provide the same effects as the stacked fan-out wafer level semiconductor package 100-1.

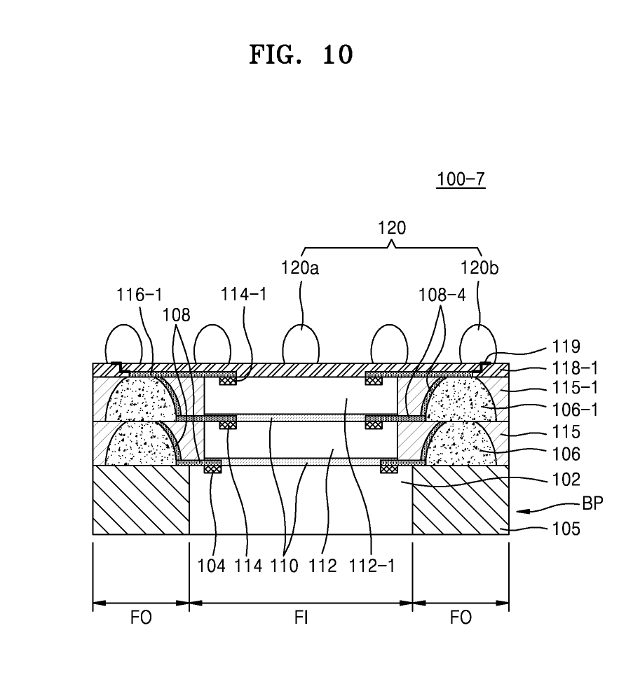

FIG. 10 is a sectional view of a main portion of a stacked fan-out wafer level semiconductor package according to an embodiment.

Specifically, a stacked fan-out wafer level semiconductor package 100-7 may be almost the same as the stacked fan-out wafer level semiconductor package 100-1 of FIGS. 2A and 2B except that a third chip 112-1 is further stacked on the second chip 112. In descriptions with reference to FIG. 10, the same reference numerals as in FIGS. 2A and 2B denote the same components, and overlapping portions will be briefly described or omitted for convenience.

The stacked fan-out wafer level semiconductor package 100-7 may include the base package BP including the fan-in region FI, which includes the first chip 102, and the first insulating layer 105a in the fan-out region FO surrounding the fan-in region FI. The first chip 102 may include the plurality of first chip pads 104.

The second chip 112 is stacked on and attached to the first chip 102 in the fan-in region FI via the adhesive layer 110. The second chip 112 may include the second chip pads 114. The support member 106 is arranged in the fan-out region FO while being apart from the first chip 102 and the second chip 112. The first redistribution layer 108 extends from the upper side of the first chip 102 to the upper side of the support member 106.

The stacked fan-out wafer level semiconductor package 100-7 may include the second insulating layer 115 protecting the first chip 102 and the second chip 112. The second redistribution layer 116 extends from the upper side of the second chip 112 to the upper side of the first redistribution layer 108. The first chip 102 and the second chip 112 are electrically connected to each other by the redistribution layers including the first redistribution layer 108 and the second redistribution layer 116.

The third chip 112-1 is stacked on and attached to the second chip 112 in the fan-in region FI via the adhesive layer 110. The third chip 112-1 may include third chip pads 114-1. A second support member 106-1 is arranged in the fan-out region FO while being apart from the third chip 112-1. A second redistribution layer 108-4 extends from the upper side of the first chip 102 to an upper side of the second support member 106-1.

The stacked fan-out wafer level semiconductor package 100-7 may include a third insulating layer 115-1 which protects the second chip 112 and insulates the second chip 112 from the third chip 112-1. A third redistribution layer 116-1 extends from an upper side of the third chip 112-1 to an upper side of the second redistribution layer 108-4. The first chip 102, the second chip 112, and the third chip 112-1 are electrically connected to each other by the redistribution layers including the first redistribution layer 108, the second redistribution layer 108-4, and the third redistribution layer 116-1. In FIG. 10, although the second chip 112 and the third chip 112-1 are different from the first chip 102, the second chip 112 and the third chip 112-1 may be the same as the first chip 102.

A fourth insulating layer 118-1 is formed on the third chip 112-1, the third redistribution layer 116-1, the second support member 106-1, and the third insulating layer 115-1. The external connection terminal 120, which is electrically connected to the redistribution layers 108, 108-4, 116-1 through the internal wiring layer 119, is formed on the fourth insulating layer 118-1 in the fan-in region FI and the fan-out region FO. The external connection terminal 120 may include the first external connection terminal 120a in the fan-in region FI and the second external connection terminal 120b in the fan-out region FO.

As such, even though the second chip 112 and the third chip 112-1 are sequentially stacked on the first chip 102, the stacked fan-out wafer level semiconductor package 100-7 can provide the same effects as the stacked fan-out wafer level semiconductor package 100-1.

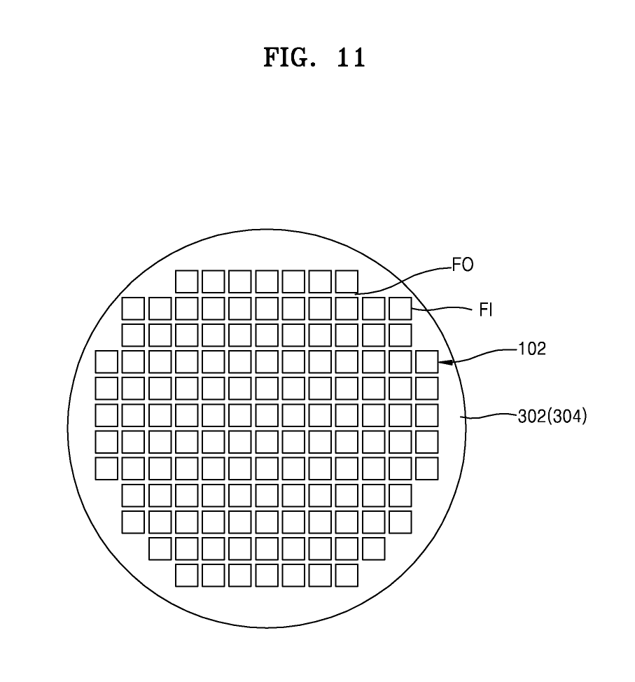

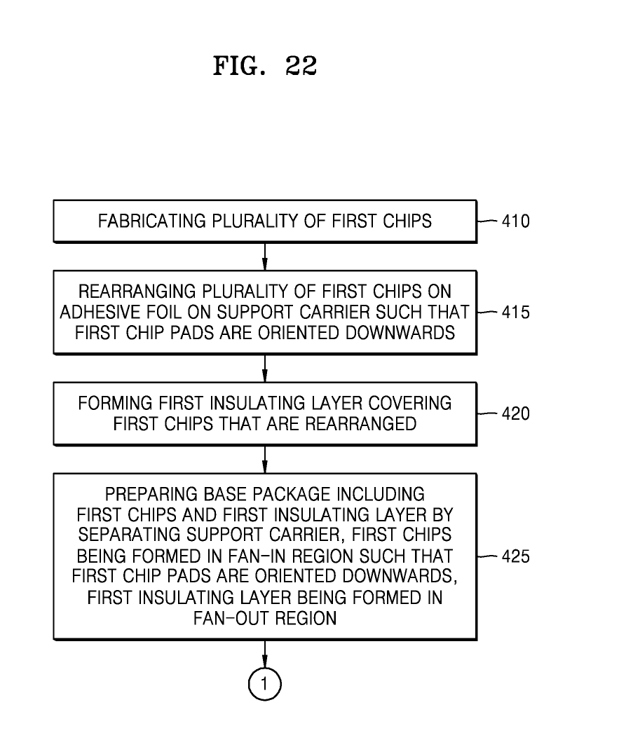

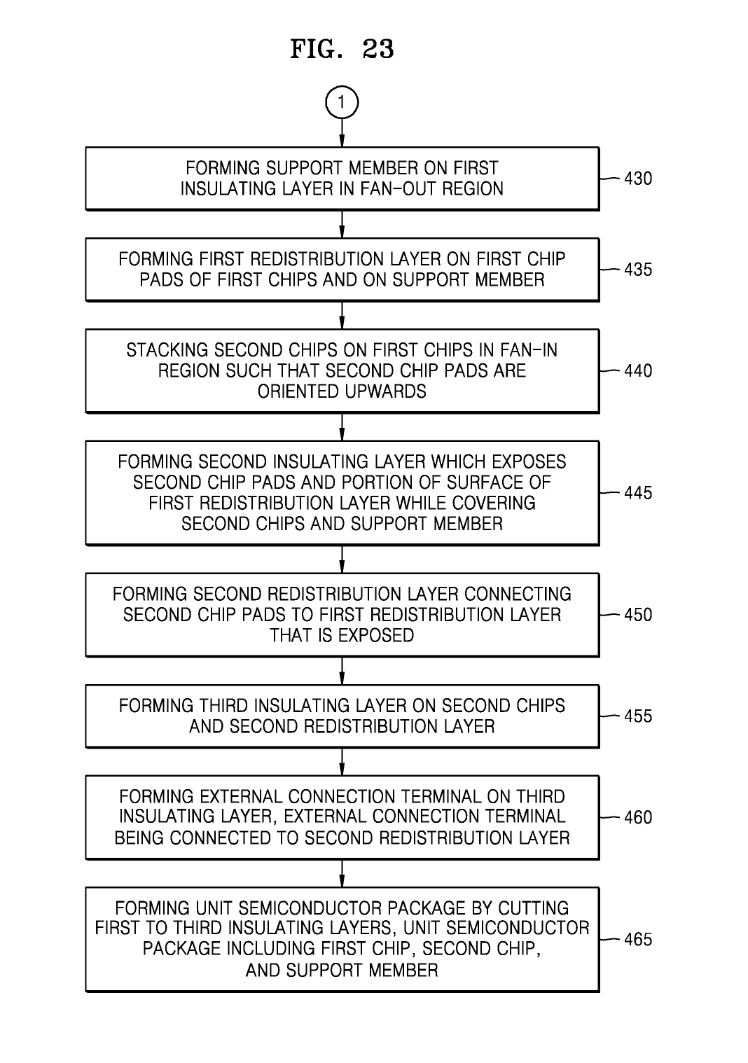

FIGS. 11 to 21 are diagrams for explaining a method of fabricating a semiconductor package according to an embodiment, and FIGS. 22 and 23 show a flow chart for explaining the method of fabricating the semiconductor package of FIGS. 11 to 21.

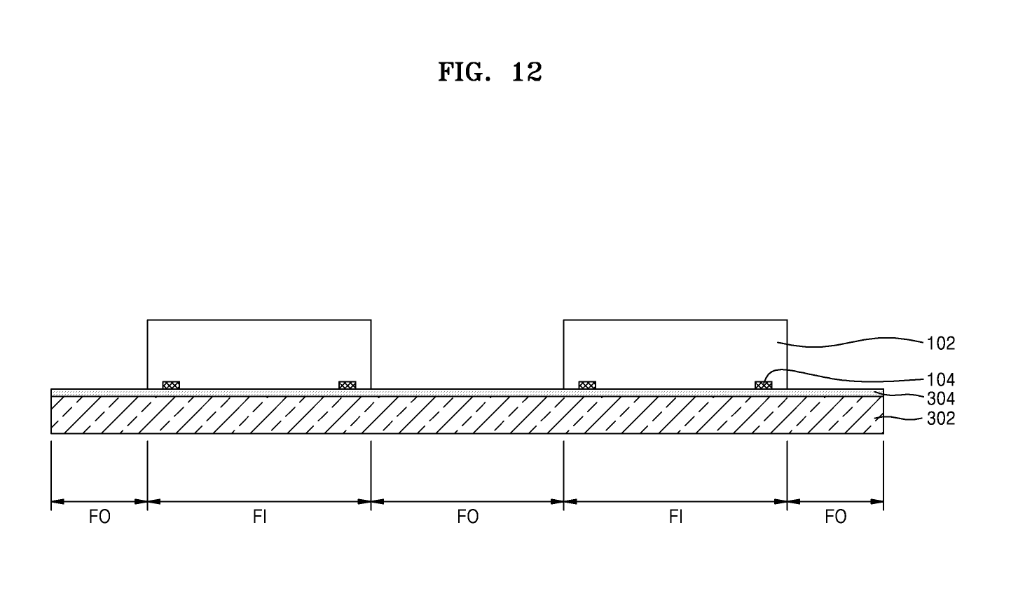

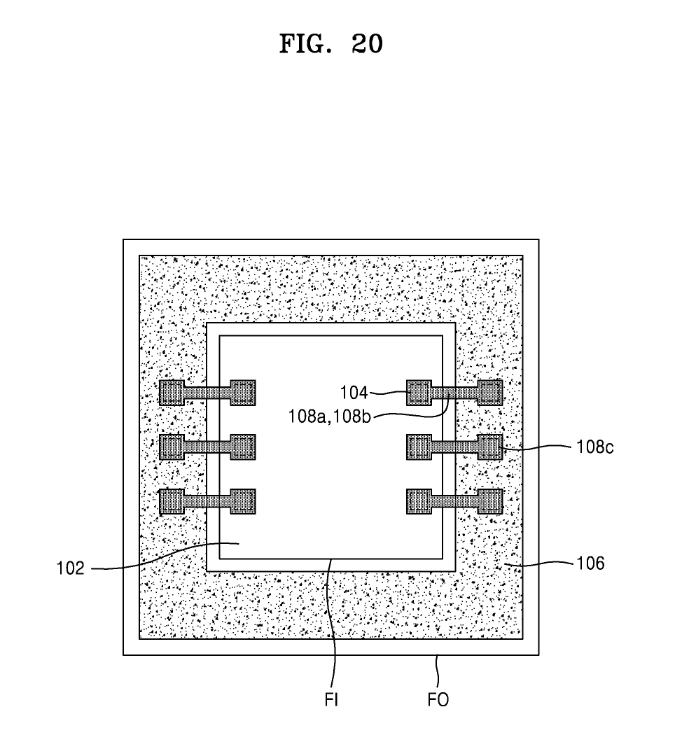

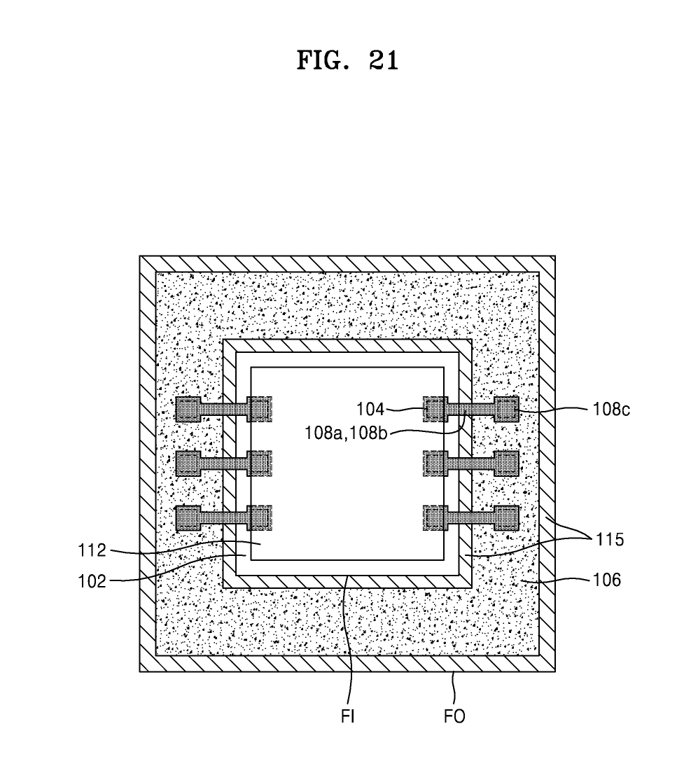

Specifically, FIG. 11 is a diagram for explaining rearranging first chips on a support carrier. FIGS. 12 to 19 are sectional views for explaining the method of fabricating the stacked fan-out wafer level semiconductor package. FIGS. 20 and 21 are plan views for explaining the method of fabricating the stacked fan-out wafer level semiconductor package.

FIGS. 11 to 21 are diagrams for explaining a method of fabricating the stacked fan-out wafer level semiconductor package of FIGS. 1A, 1B, 2A, and 2B. In descriptions with reference to FIGS. 11 to 21, the same reference numerals as in FIGS. 1A, 1B, 2A, and 2B denote the same components, and overlapping portions will be briefly described or omitted for convenience.

A plurality of first chips 102 in FIGS. 11 and 12 are fabricated on a wafer, for example, a silicon wafer through a wafer fabrication process (operation 410 in FIG. 22). Fabrication of the first chips 102 through the wafer fabrication process is well known to those skilled in the art, and thus will not be described herein for convenience.

Referring to FIGS. 11, 12, and 22, the first chips 102 are rearranged on an adhesive foil 304 of a support carrier 302 at a wafer level (operation 415). The support carrier 302 may include silicon, germanium, silicon germanium, gallium arsenide (GaAs), glass, metal, plastic, and ceramic substrates. The support carrier 302 may have a wafer shape, as shown in FIG. 11. A region in which the first chips 102 are arranged may be the fan-in region FI. A region around the fan-in region FI may be the fan-out region FO. In some embodiments, the first chips 102 are arranged in the fan-in region FI that is defined in the adhesive foil 304 of the support carrier 302, and the region around the fan-in region FI is defined as the fan-out region FO.

When rearranged on the adhesive foil 304 on the support carrier 302, the first chips 102 are rearranged such that the first chip pads 104 of the first chips 102 face the support carrier 302 downwards. Thus, the first chip pads 104 are brought into contact with the adhesive foil 304 on the support carrier 302 and attached thereto.

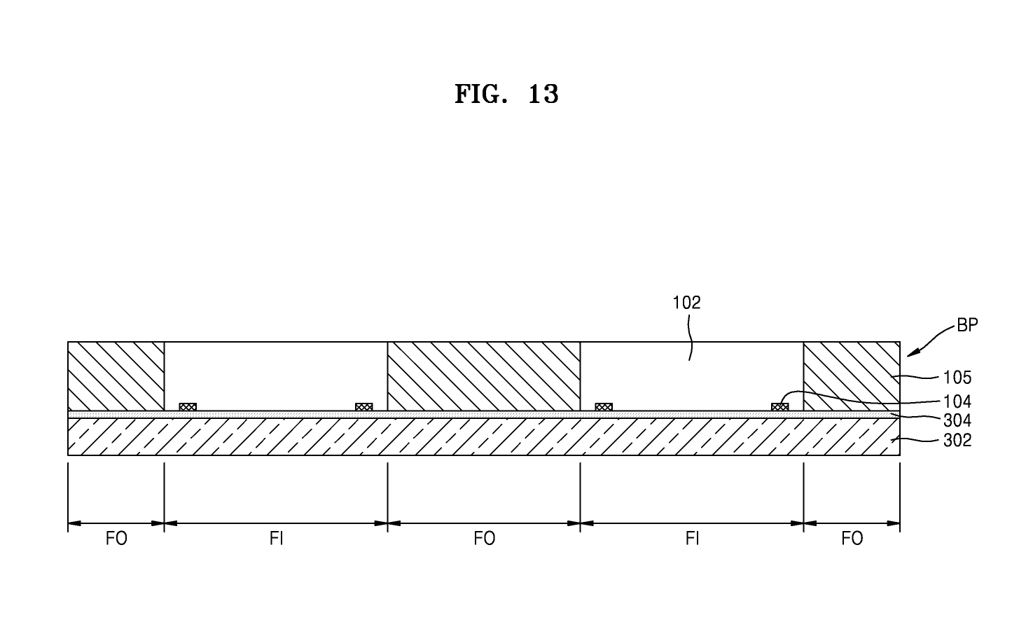

Referring to FIGS. 13, 14, and 22, as shown in FIG. 13, the first insulating layer 105 is formed in the fan-out region FO around the first chips 102 which are rearranged in the fan-in region FI at a wafer level (operation 420). Thus, the base package BP, which includes the first chips 102 rearranged in the fan-in region FI at a wafer level and the first insulating layer 105 formed in the fan-out region FO around the fan-in region FI, is formed.

The first insulating layer 105 may be obtained by forming a molding layer around the first chips 102 through molding of the first chips 102 rearranged on the adhesive foil 304 on the support carrier 302. The first insulating layer 105 may be formed by forming a molding layer to cover the first chips 102 rearranged on the adhesive foil 304 on the support carrier 302, followed by etching the molding layer such that surfaces of the first chips 102 are exposed. The first insulating layer 105 may be formed of a molding layer, for example, an epoxy resin layer.

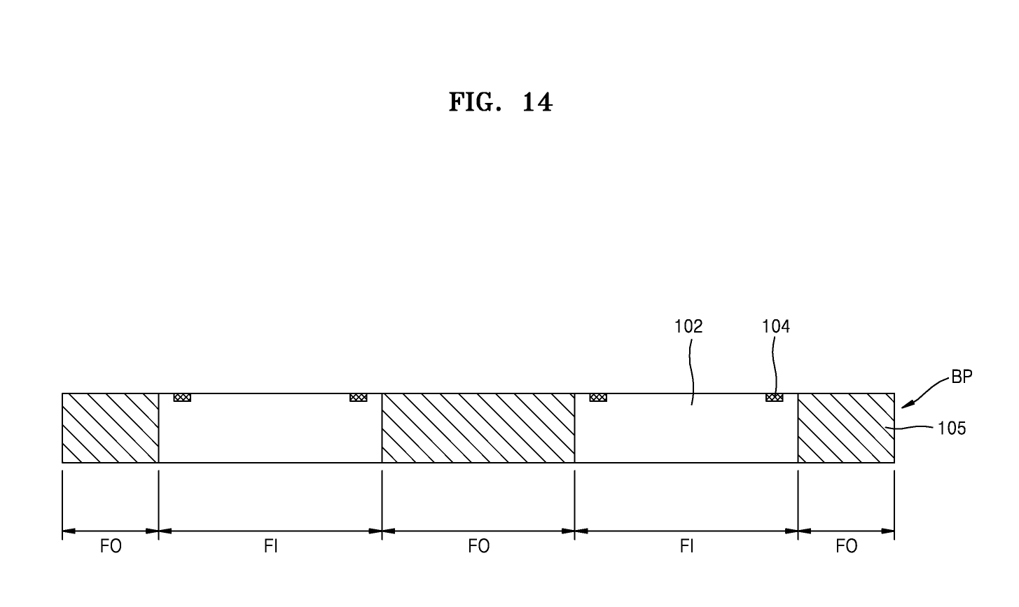

As shown in FIG. 14, the first chips 102 and the first insulating layer 105 are separated from the support carrier 302 by debonding the adhesive foil 304. Thus, the base package BP including the first chips 102 and the first insulating layer 105 is prepared (operation 425). FIG. 14 shows a state in which the first chip pads 104 are formed on the upper surface of the first chips 102, since the base package BP is turned over.

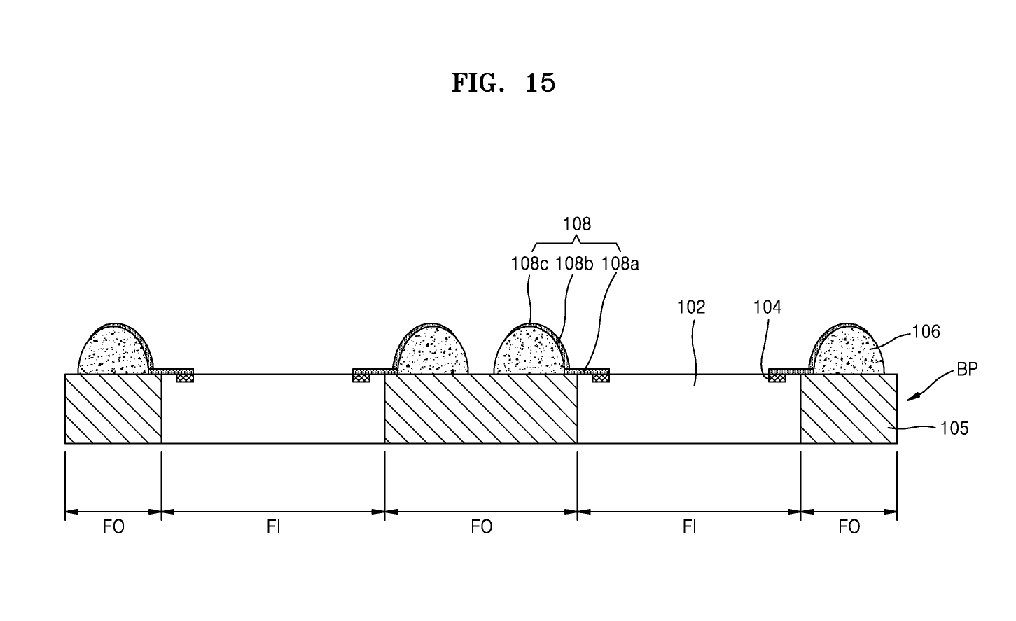

Referring to FIGS. 15 and 20, the support member 106 is formed on the first insulating layer 105 in the fan-out region FO. Here, the support member 106 is formed such that the first chip pads 104 of the first chips 102 are exposed upwards. The support member 106 is formed, for example, as a dam member which is formed on the first insulating layer 105 to protrude above the first insulating layer and surround the first chip 102. The support member 106 may be a continuous structure and may fully surround the first chip 102. However, the implementations of the various packages described herein are not limited to this embodiment.

The support member 106 may be formed, for example, by forming a polymer layer on the first insulating layer 105, followed by flowing the polymer layer through heat treatment thereof. Thus, the support member 106 may include the polymer layer, and may have a semi-elliptical cross section.

The support member 106 may have a semi-elliptical or quadrangular cross section according to a degree of flow of the polymer layer. The support member 106 may be formed of a non-conductive member other than the polymer layer. The support member 106 may be formed to correspond to a height of the second chip 112 that is stacked afterwards.

The first redistribution layer 108 is formed on the first chips 102 and the support member 106. The first redistribution layer 108 may be formed on the surfaces of the first chips 102, which includes the first chip pads 104, and on one side surface of the support member 106. As described above, the first redistribution layer 108 may include the first sub-redistribution layer 108a on the first chip pad 104, the first chip 102, and the first insulating layer 105, the second sub-redistribution layer 108b on the one side surface of the support member 106, and the third sub-redistribution layer 108c on the surface of the support member 106. As shown in FIG. 15, a plurality of redistribution lines 108 may be formed to extend from the surface (e.g., top surface) of the first chip to a surface (e.g., top surface, such as a top-most surface) of the support member 106. Each redistribution line 106 may be formed, for example, a process that patterns a conductive layer on the first chip 102, the first insulating layer 105, and the support member 106. The process may include, for example, a plating process, a photolithography process, or an etching process. For example, the first redistribution layer 108 may be formed using an electroplating process.

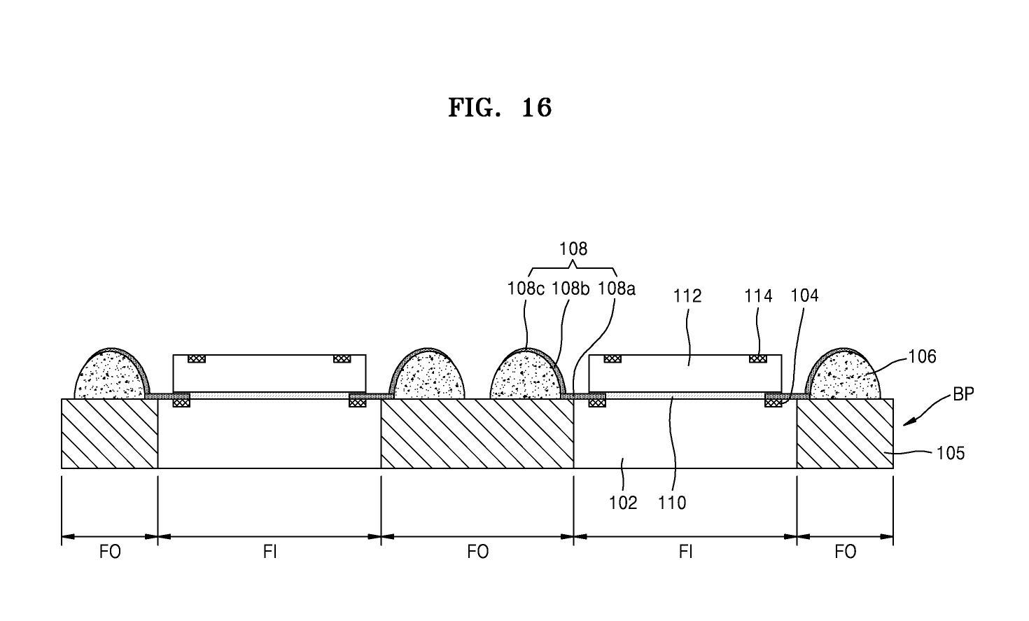

Referring to FIGS. 16, 17, and 21, as shown in FIGS. 16 and 21, the second chips 112 are respectively stacked on the first chips 102 in the fan-in region FI by interposing the adhesive layers 110 therebetween. Here, the second chips 112 may be respectively stacked on the first chips 102 such that the second chip pads 114 of the second chips 112 are oriented upwards. Each first chip pad 104 and redistribution line 108 may contact each other and be electrically and physically attached to each other.

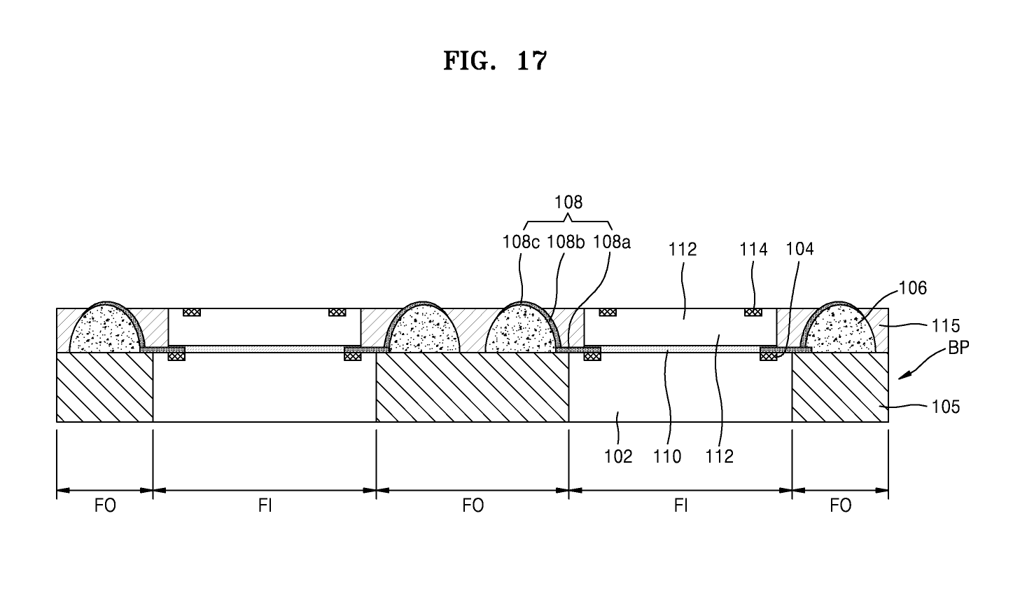

Next, as shown in FIGS. 17 and 21, the second insulating layer 115, which exposes the upper surface of the first redistribution layer 108 while covering the second chips 112 and the support member 106, is formed. The second insulating layer 115 may protect the first chips 102 and the second chips 112, and may insulate the first chips 102 from the second chips 112. The second insulating layer 115 may surround the second chips 112 and the support member 106. The second insulating layer 115 may be a coating layer surrounding the second chips 112 and the support member 106.

As described above, the second insulating layer 115 may be formed of an oxide layer, a nitride layer, a polymer layer, or combinations thereof. The second insulating layer 115 may be formed using chemical vapor deposition (CVD), spin coating, physical vapor deposition (PVD), or the like.

The second insulating layer 115 is formed around the second chips 112 and the support member 106 such that the surfaces of the second chips 112 and the upper surface of the first redistribution layer 108, for example, the third sub-redistribution layer 108c are exposed. In one embodiment, the second insulating layer 115 surrounds the second chips 112 and the support members 106 while exposing the surfaces of the second chips 112 and the upper surface of the first redistribution layer 108, for example, the third sub-redistribution layer 108c.

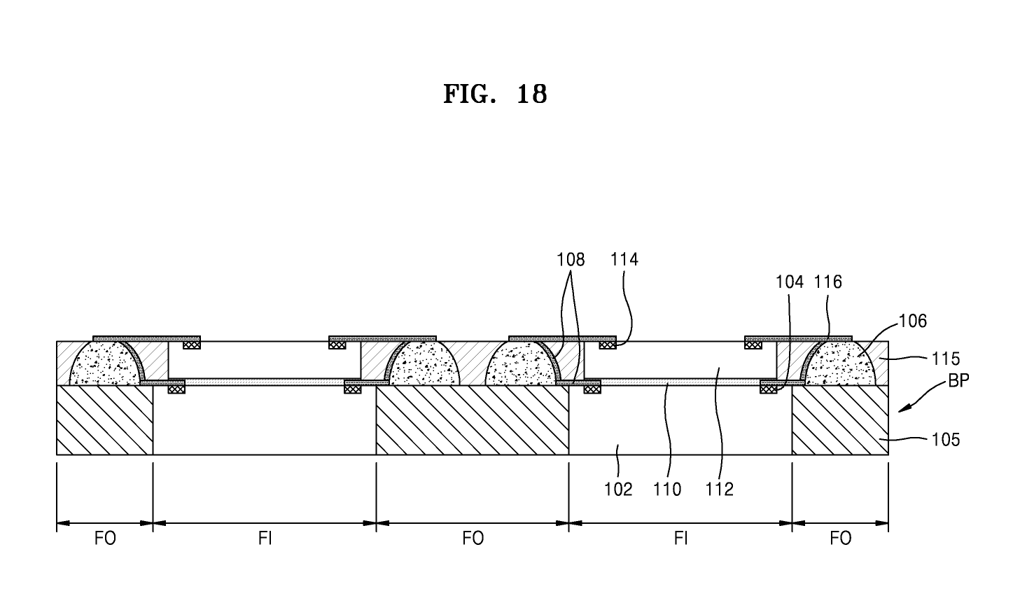

Referring to FIG. 18, the second redistribution layer 116, which electrically connects the second chips 112 to the first redistribution layer 108 that is exposed, is formed. The second redistribution layer 116 is formed on the surfaces of the second chip pads 114, the second chips 112, the second insulating layer 115, and the first redistribution layer 108 that is exposed.

The second redistribution layer 116 may electrically connect the second chip pads 114 of the second chips 112 to the first redistribution layer 108 that is exposed. As a result, the first chips 102 can be electrically connected to the second chips 112 by the redistribution layers including the first redistribution layer 108 and the second redistribution layer 116.

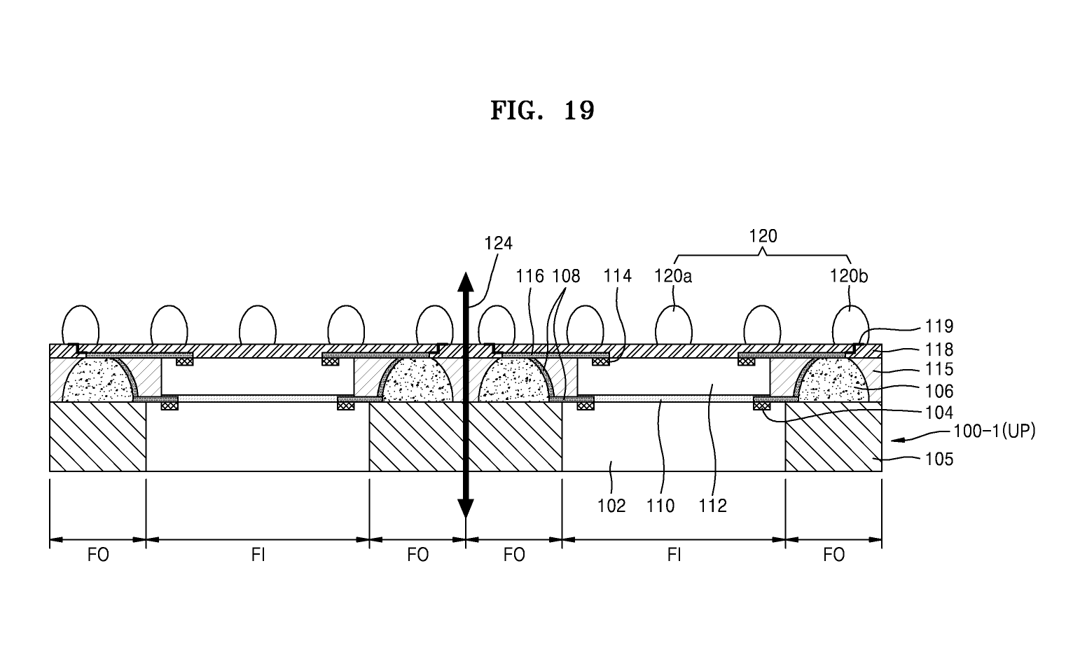

Referring to FIG. 19, the third insulating layer 118 is formed on the second chips 112, the second redistribution layer 116, the support member 106, and the second insulating layer 115. Next, the external connection terminal 120, which is electrically connected to the second redistribution layer 116, is formed on the third insulating layer 118 in the fan-in region FI and the fan-out region FO.

The external connection terminal 120 is formed on the third insulating layer 118 in the fan-in region FI and the fan-out region FO, and is electrically connected to the redistribution layers 108, 116 through the internal wiring layer 119. The external connection terminal 120 may be electrically connected to the first redistribution layer 108 through the internal wiring layer 119 and the second redistribution layer 116. The external connection terminal 120 may include the first external connection terminal 120a formed in the fan-in region FI and the second external connection terminal 120b formed in the fan-out region FO.

Next, a unit semiconductor package UP, which includes the first chip 102, the second chip 112, and the support member 106, is formed by cutting the first insulating layer 105, the second insulating layer 115, and the third insulating layer 118 along a cutting line 124. The unit semiconductor package UP may be the stacked fan-out wafer level semiconductor package 100-1 described above.

Referring to the above figures, beginning with FIG. 2A as an example, though the first chip 102 and first insulating layer 105 may be described herein as a base package BP, they also may be described as a semiconductor chip and molding layer of a semiconductor package. For example, when the package 100-1 shown in FIG. 2A is a singulated package, it may be viewed from an upside-down perspective from that shown in FIG. 2A. In such a perspective, chip 102 may be an upper chip of the package, also described as a second chip, chip 112 may be a lower chip of the package, also described as a first chip, insulating layer 105 may be referred to as a molding layer, upper molding layer, or upper insulating layer 105, insulating layer 115 may be referred to as a lower molding layer, or lower insulating layer 115, and insulating layer 118 may be described as a package substrate, or package base layer 118. In addition, support member 106, which may be formed of an insulating material, may be considered as part of the lower molding layer or lower insulating layer. Upper molding layers 105 and lower molding layer 115/106 may be referred to in combination as a molding layer, or encapsulation layer. In some embodiments, as shown for example in FIG. 9, the upper molding layer 105a may extend above and cover a top surface of the upper chip 102.

Further along these lines, redistribution layer 116 may be described as being formed on the package substrate 118, and may be described generally as wiring or redistribution lines formed on the package substrate 118. Redistribution lines 116 may be formed at a single vertical level and extending horizontally. Redistribution layer 108 may be described generally as wiring or as a redistribution line. Further, portion 108a of redistribution layer 108 may be referred to as a portion (e.g., first portion) of a redistribution line, or simply a redistribution line (e.g., formed at a single vertical level and extending horizontally), while portions 108b and 108c may be referred to as a portion (e.g., second portion) of a redistribution line, or as a wire extending between a first redistribution line (e.g., 108a, which may be a redistribution line for the first chip 102) at a first vertical level, and a second redistribution line (e.g., 116, which may be a redistribution line for the second chip 112) at a second vertical level. Thus, a wire formed of portions 108b and 108c may extend both vertically and horizontally so that it is formed through a range of vertical levels.

As can be seen in FIG. 2A and various other figures, a semiconductor package is provided that may have external connection terminals (e.g., 120) for connecting to outside of the package at a bottom of the package. The external connection terminals maybe provided at a bottom surface of a package substrate (e.g., 118, also described as a package base layer). The package substrate may include redistribution lines thereon (e.g., 116), and may include wiring (e.g., 119) passing through the substrate and electrically connecting the external connection terminals to the redistribution lines (e.g., 116) formed on the substrate. The redistribution lines may connect to conductive pads (e.g., 114) at a bottom surface of a first chip (e.g., 112). The bottom surface may be an active surface of the first chip 112. For example, the redistribution lines (e.g., 116) may extend horizontally and may contact the pads 114 to form an electrical connection. The redistribution lines 116 may contact the pads 114 at a first end, or first portion of the redistribution lines 116. The redistribution lines 116 may be provided at a vertical location that is between a vertical level at which the pads 114 are provided and a vertical level at which the external connection terminals 120 are provided.

The redistribution lines 116 may also contact, or connect to, wires (e.g., 108b and 108c) that pass through an insulating layer surrounding the first chip 112. The insulating layer surrounding the first chip 112, also referred to as a molding layer or first insulating layer, may include insulating layer 115 and support member 106. The combination of a section 108b and 108c such as shown in FIGS. 2A and 2B may be formed of a continuous conductive line, and may be conformally formed on a portion of the insulating layer that surrounds the first chip 112. For example, the combination of section 108b and 108c may be described as a wire that passes through the bottom insulating layer. The wire may be disposed at a boundary between a first structure (e.g., support structure 106) of the bottom insulating layer and a second structure (e.g., insulating layer 115) of the bottom insulating layer. The boundary may be a surface boundary, between surfaces of the first and second structure. One end of the wire may contact a first redistribution line 116 to electrically connect to the redistribution line 116, and the other end of the wire may contact a second redistribution line 108a to electrically connect to the redistribution line 108a.

The second redistribution line 108a may be provided to contact and electrically connect to a conductive pad (e.g., 104) provided at a surface, such as a bottom surface, of the second chip 102. The bottom surface may be an active surface of the second chip 102.

Thus, as can be seen from this perspective, the wire (108b and 108c) may have a shape different from both traditional wire bonding wires, and different from traditional through vias. For example, the wire (108b and 108c) passing through the vertical level of the first chip 112 and formed horizontally outside of the first chip 112 may have a shape that bulges inwardly on the package 100-1 toward the first chip 112, and may be concave in relation to a center of the package 100-1 and/or a center of the first chip 112. The wire may have a curved shape, as shown in FIGS. 2A and 2B. The wire, from one terminal end to the opposite terminal end, may be horizontally outside of the region occupied by the first chip 112. The wire may be formed vertically only between a first redistribution line (e.g., 116) disposed at a bottom surface of the lower chip 112 and a second redistribution line (e.g., 108a) disposed at bottom surface of the upper chip 102. The wire may pass between two separately-formed portions (e.g., which may be formed of different materials) of an insulating layer that surrounds the first chip 112. For example, the wire may be conformally formed on a support structure that is part of the insulating layer that surrounds the first chip 112. In some embodiments, such as in FIG. 6 and FIG. 7, the wires that extend between a lower redistribution line formed at a bottom surface of first chip and an upper redistribution line formed at a bottom surface of a second chip have angled shapes, but still remain in a shape that bulges toward the semiconductor chip and is concave with respect to the center of the package. For example, of these embodiments show a wire that bends away from the package substrate, as the wire gets horizontally closer to the semiconductor chip.

As can be further seen from the various method figures, in providing the package substrate, external connection terminals, lower chip (e.g., the chip closer to the package substrate when viewed with the external connection terminals at the bottom of the package), upper chip, redistribution lines on the lower chip, redistribution lines on the lower chip, and wires connecting the different redistribution lines, in some embodiments, the redistributions lines of the package substrate may be formed before the insulating layer of the package substrate (e.g., the package substrate) is formed. Also, the molding layer surrounding the semiconductor chips may be formed on the semiconductor chips prior to forming the package substrate. In addition, in some embodiments, the wires (e.g., combined 108b and 108c) may be formed at the same time as the redistribution lines formed on the bottom surface of the upper chip (e.g., 108a), and therefore each wire (e.g., 108b and 108c) and its corresponding redistribution line (e.g., 108a) may be a single, continuous, integral line, or structure.

Based on the structures and method described above, stacked chip packages can be provided to have smaller thicknesses and higher yield.

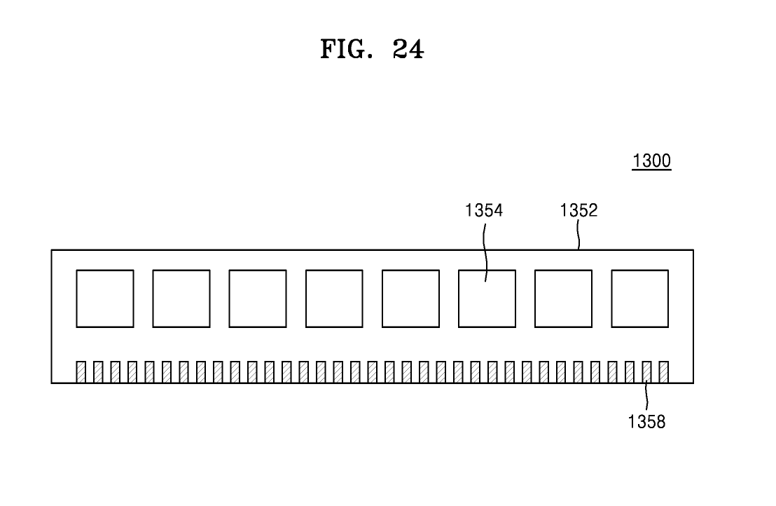

FIG. 24 is a schematic plan view of a semiconductor module including a stacked fan-out wafer level semiconductor package according to an embodiment.

Specifically, a semiconductor module 1300 includes a module substrate 1352, a plurality of semiconductor packages 1354 on the module substrate 1352, and module contact terminals 1358 which are formed side by side in contiguity with one edge of the module substrate 1352 and each electrically connected to the semiconductor packages 1354.

The module substrate 1352 may be a printed circuit board (PCB). Both surfaces of the module substrate 1352 may be used. That is, the semiconductor packages 1354 may be arranged on both front and back surfaces of the module substrate 1352. Although eight semiconductor packages 1354 are shown as being arranged on the front surface of the module substrate 1352 in FIG. 24, this is merely an example. The semiconductor module 1300 may further include a separate semiconductor package for controlling the semiconductor packages 1354.

At least one of the semiconductor packages 1354 may be the stacked fan-out wafer level semiconductor package according to the embodiments described above. The module contact terminals 1358 may be formed of a metal, and have oxidation resistance. The module contact terminals 1358 may be variously set according to standards of the semiconductor module 1300. Therefore, there is no special meaning in the number of the illustrated module contact terminals 1358.

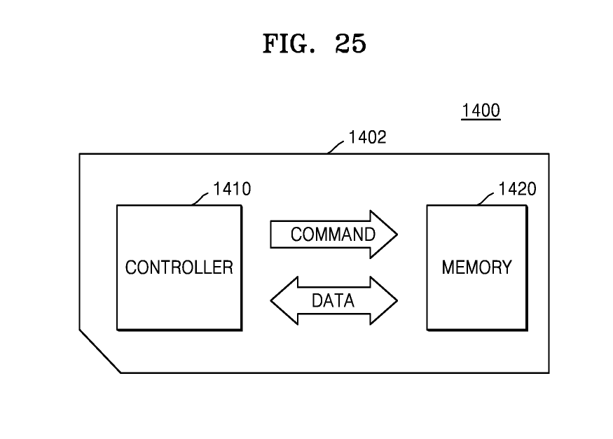

FIG. 25 is a schematic diagram of a card including a stacked fan-out wafer level semiconductor package according to an embodiment.

Specifically, a card 1400 may include a controller 1410 and a memory 1420, which are arranged on a circuit board 1402. The controller 1410 and the memory 1420 may exchange electrical signals with each other. For example, if the controller 1410 gives a command to the memory 1420, the memory 1420 may transmit data. The memory 1420 or the controller 1410 may include the stacked fan-out wafer level semiconductor package according to the embodiments.

The card 1400 may include various cards, for example, a memory stick card, a smart media card (SM), a secure digital card (SD), a mini secure digital card (mini SD), or a multi-media card (MMC).

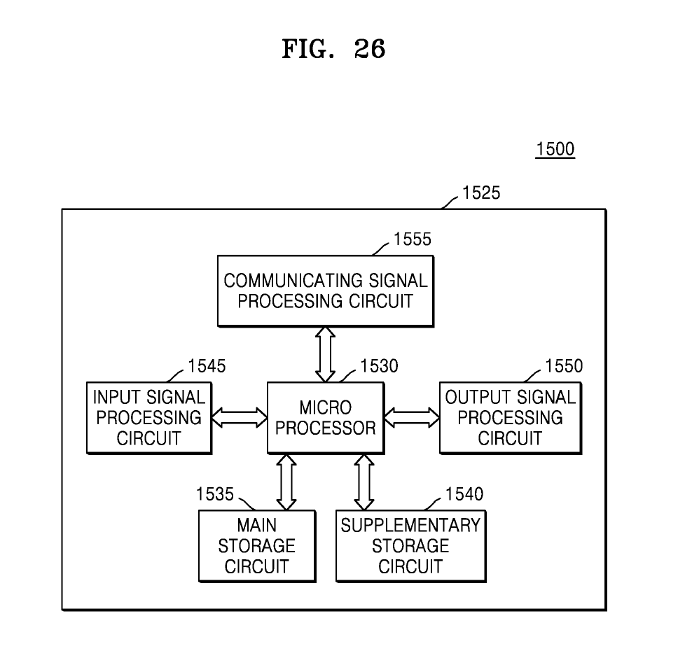

FIG. 26 is a schematic block diagram of an electronic circuit board including a stacked fan-out wafer level semiconductor package according to an embodiment.

Specifically, an electronic circuit board 1500 includes a microprocessor 1530, a main storage circuit 1535 and a supplementary storage circuit 1540 communicating with the microprocessor 1530, an input signal processing circuit 1545 sending commands to the microprocessor 1530, an output signal processing circuit 1550 receiving commands from the microprocessor 1530, and a communicating signal processing circuit 1555 sending signals to and receiving signals from other circuit boards, the components stated above being arranged on a circuit board 1525. It can be understood that arrows in FIG. 26 mean paths through which electrical signals can be transferred.

The microprocessor 1530 may receive and process various electrical signals, output processed results, and control other components of the electronic circuit board 1500. The microprocessor 1530 may include, for example, a central processing unit (CPU), a main control unit (MCU), and/or the like.

The main storage circuit 1535 may temporarily store data that is always or frequently required by the microprocessor 1530, or data before and after processing. Since the main storage circuit 1535 requires a fast response speed, the main storage circuit 1535 may include a semiconductor memory chip. More specifically, the main storage circuit 1535 may be a semiconductor memory referred to as a cache, and may include a static random access memory (SRAM), a dynamic random access memory (DRAM), a resistive random access memory (RRAM), and applications thereof, for example, a utilized RAM, a ferro-electric RAM, a fast cycle RAM, a phase changeable RAM, a magnetic RAM, and other semiconductor memories.

In addition, it does not matter at all whether the main storage circuit 1535 is volatile/nonvolatile, and the main storage circuit 1535 may include a random access memory. The main storage circuit 1535 may include at least one semiconductor package or semiconductor module according to the embodiments described herein. The supplementary storage circuit 1540 is a mass storage element, and may be a nonvolatile semiconductor memory such as a flash memory, or be a hard disk drive using a magnetic field. Alternatively, the supplementary storage circuit 1540 may be a compact disk drive using light. The supplementary storage circuit 1540 may be used when the supplementary storage circuit 1540 needs to store massive data while not requiring a fast speed, as compared with the main storage circuit 1535. It does not matter at all whether the supplementary storage circuit 1540 is of random type/non-random type, and the supplementary storage circuit 1540 may include a nonvolatile storage element.

The supplementary storage circuit 1540 may include the stacked fan-out wafer level semiconductor package or the semiconductor module according to the disclosed embodiments. The input signal processing circuit 1545 may convert a command external to the electronic circuit board 1500 into an electrical signal, or transfer an electrical signal, which is transferred from the outside of the electronic circuit board 1500, to the microprocessor 1530.

The command or electrical signal transferred from the outside of the electronic circuit board 1500 may be an operation command, an electrical signal to be processed, or data to be stored. The input signal processing circuit 1545 may include, for example, a terminal signal processing circuit, which processes signals transferred from a keyboard, a mouse, a touch pad, an image recognizing device, or various sensors, an image signal processing circuit, which processes image signals that are input from a scanner or camera, various sensors or input signal interfaces, or the like. The input signal processing circuit 1545 may include the stacked fan-out wafer level semiconductor package or the semiconductor module according to the disclosed embodiments.

The output signal processing circuit 1550 may be a component for transmitting an electrical signal processed by the microprocessor 1530 to the outside of the electronic circuit board 1500. For example, the output signal processing circuit 1550 may be a graphic card, an image processor, an optical converter, a beam panel card, an interface circuit having various functions, or the like. The output signal processing circuit 1550 may include the stacked fan-out wafer level semiconductor package or the semiconductor module according to the disclosed embodiments.

The communication circuit 1555 is a component for directly sending electrical signals to and directly receiving electrical signals from other electronic systems or other circuit boards without use of the input signal processing circuit 1545 or the output signal processing circuit 1550. For example, the communication circuit 1555 may include a modem of a personal computer system, a LAN card, various interface circuits, or the like. The communication circuit 1555 may include the stacked fan-out wafer level semiconductor package or the semiconductor module according to the disclosed embodiments.

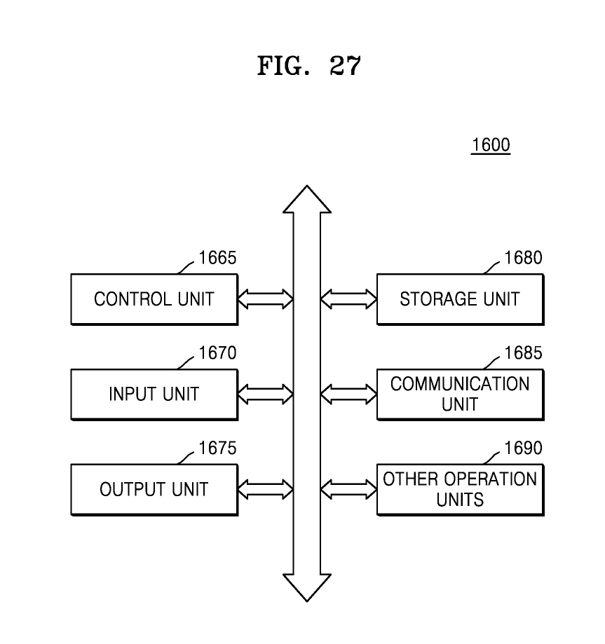

FIG. 27 is a schematic block diagram of an electronic system including a stacked fan-out wafer level semiconductor package according to an embodiment.

Specifically, an electronic system 1600 includes a control unit 1665, an input unit 1670, an output unit 1675, and a storage unit 1680, and may further include a communication unit 1685 and/or other operation units 1690.

The control unit 1665 may collectively control the electronic system 1600 and each of the components. The control unit 1665 may be a central processing unit or a central controlling unit, and may include the electronic circuit board 1500 of FIG. 26 according to the embodiment. In addition, the control unit 1665 may include the stacked fan-out wafer level semiconductor package or the semiconductor module according to the disclosed embodiments.

The input unit 1670 may send electrical command signals to the control unit 1665. The input unit 1670 may include a keyboard, a keypad, a mouse, a touch pad, an image recognizer such as a scanner, or various input sensors. The input unit 1670 may include the stacked fan-out wafer level semiconductor package or the semiconductor module according to the disclosed embodiments.

The output unit 1675 may receive electrical signals from the control unit 1665, and output results processed by the electronic system 1600. The output unit 1675 may include a monitor, a printer, a beam projector, or various mechanical devices. The output unit 1675 may include the stacked fan-out wafer level semiconductor package or the semiconductor module according to the disclosed embodiments.

The storage unit 1680 may be a component for temporarily or permanently storing electrical signals which are to be processed or have been processed by the control unit 1665. The storage unit 1680 may be physically or electrically connected or coupled to the control unit 1665. The storage unit 1680 may include a semiconductor memory, a magnetic storage device such as a hard disk, an optical storage device such as a compact disk, or other servers having a data storing function. In addition, the storage unit 1680 may include the stacked fan-out wafer level semiconductor package or the semiconductor module according to the disclosed embodiments.

The communication unit 1685 may receive electrical command signals from the control unit 1665, and send electrical signals to or receive electrical signals from other electronic systems. The communication unit 1685 may include a wired transceiver such as a modem or a LAN card, a wireless transceiver such as a WiBro interface, an infrared port, or the like. In addition, the communication unit 1685 may include the stacked fan-out wafer level semiconductor package or the semiconductor module according to the disclosed embodiments.

The other operation units 1690 may perform physical or mechanical operations according to commands of the control unit 1665. For example, the other operation units 1690 may be components performing mechanical operations, such as plotters, indicators, up/down operators, or the like. The electronic system 1600 may include a computer, a network server, a network printer, a scanner, a wireless controller, a terminal for mobile communications, a switching system, or other electronic elements performing programmed operations.

In addition, the electronic system 1600 may be used for mobile phones, MP3 players, navigation systems, portable multimedia players (PMPs), solid state disks (SSDs), or household appliances.

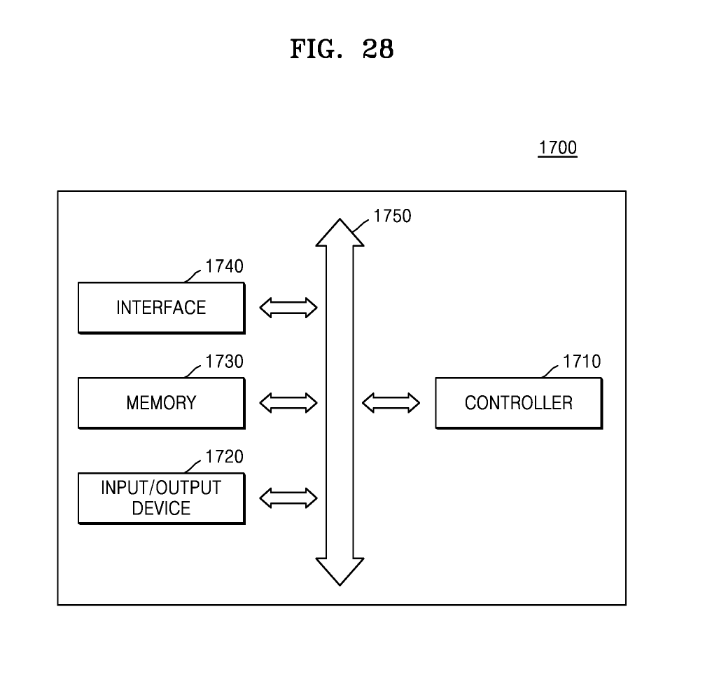

FIG. 28 is a schematic diagram of an electronic system including a stacked fan-out wafer level semiconductor package according to an embodiment.

Specifically, an electronic system 1700 may include a controller 1710, an input/output device 1720, a memory 1730, and an interface 1740. The electronic system 1700 may be a mobile system or a system for transmitting or receiving information. The mobile system may be a PDA, a portable computer, a web tablet, a wireless phone, a mobile phone, a digital music player, or a memory card.

The controller 1710 may serve to execute programs and to control the electronic system 1700. The controller 1710 may include the stacked fan-out wafer level semiconductor package according to the inventive concept. The controller 1710 may be, for example, a microprocessor, a digital signal processor, a microcontroller, or a device that is similar thereto.

The input/output device 1720 may be used to input or output data of the electronic system 1700. The electronic system 1700 may be connected to devices external to the electronic system 1700, for example, a personal computer or a network by using the input/output device 1720, and thus exchange data with the external devices. The input/output device 1720 may be, for example, a keypad, a keyboard, or a display.

The memory 1730 may store codes and/or data for operations of the controller 1710, and/or may store data processed by the controller 1710. The memory 1730 may include the stacked fan-out wafer level semiconductor package according to the disclosed embodiments. The interface 1740 may be a data transmitting path between the electronic system 1700 and other devices external to the electronic system 1700. The controller 1710, the input/output device 1720, the memory 1730, and the interface 1740 may communicate with each other through a bus 1750.

For example, the electronic system 1700 may be used for mobile phones, MP3 players, navigation systems, portable multimedia players (PMPs), solid state disks (SSDs), or household appliances.

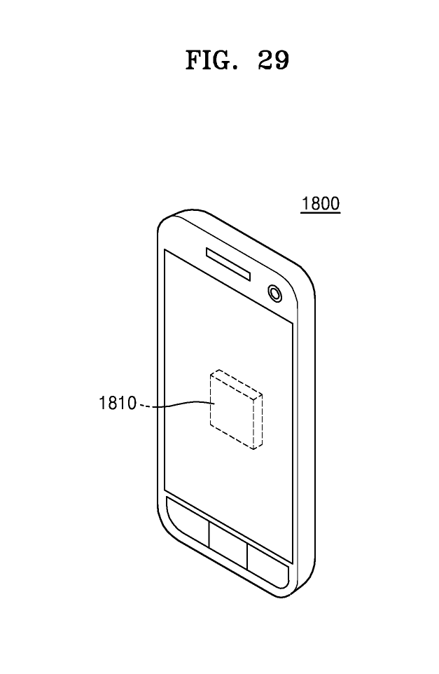

FIG. 29 is a schematic perspective view of an electronic device including a stacked fan-out wafer level semiconductor package according to an embodiment.

Specifically, FIG. 29 shows an example in which the electronic system 1700 of FIG. 28 is applied to a mobile phone 1800. The mobile phone 1800 may include a system-on-chip 1810. The system-on-chip 1810 may include the stacked fan-out wafer level semiconductor package according to the disclosed embodiments. Since the mobile phone 1800 may include the system-on-chip 1810 which can include a main functional block exhibiting relatively high performance, the mobile phone 1800 can exhibit relatively high performance. In addition, since the system-on-chip 1810 can exhibit relatively high performance even though having the same area, the mobile phone 1800 can exhibit relatively high performance even while having a minimized size.

While various aspects of the inventive concept has been particularly shown and described with reference to embodiments thereof, it will be understood that various changes in form and details may be made therein without departing from the spirit and scope of the following claims.

1. A method, comprising:
providing a package substrate;
providing external connection terminals on a bottom surface of the package substrate;
providing a first semiconductor chip on a top surface of the package substrate, the first semiconductor chip having a bottom surface facing the package substrate and a top surface opposite the bottom surface, and having a first conductive pad at the bottom surface;
providing a second semiconductor chip on the first semiconductor chip, the second semiconductor chip having a bottom surface facing the top surface of the first semiconductor chip and a top surface opposite the bottom surface, and having a second conductive pad at the bottom surface;
providing an insulating layer surrounding outer side surfaces of the first semiconductor chip;
providing a first redistribution line extending from the first conductive pad to a region laterally outside of the first semiconductor chip, the first redistribution line disposed on the top surface of the package substrate and on the bottom surface of the first semiconductor chip, the first redistribution extending horizontally; and
providing a second redistribution line extending from the second conductive pad to the region laterally outside of the first semiconductor chip, the second redistribution line including a first portion extending from the second conductive pad to the region laterally outside of the first semiconductor chip and a second portion extending between the first portion and the first redistribution line, and extending horizontally and vertically between the first portion and the first redistribution line.

2. The method of claim 1, wherein the second portion of the second redistribution line is disposed at a border between a first structure of the insulating layer and a second structure of the insulating layer at a surface of the first structure and a surface of the second structure.

3. The method of claim 1, wherein the second portion of the second redistribution line has a concave shape with respect to a center of the first semiconductor chip.

4. The method of claim 1, wherein the first portion of the second redistribution line and the second portion of the second redistribution line are integrally formed of a continuous conductive material.

5. The method of claim 4, further comprising:
forming the first portion of the second redistribution line at the same time as forming the second portion of the second redistribution line.

6. The method of claim 1, wherein the package substrate is formed on the first semiconductor chip after forming the first redistribution line.

7. The method of claim 1, wherein the second redistribution line extends from the second conductive pad at a location vertically below the second semiconductor chip to the top surface of the package substrate.

8. The method of claim 1, wherein the second portion of the second redistribution line is conformally formed on an insulating structure that forms part of the insulating layer.

9. The method of claim 8, wherein the second portion of the second redistribution line has a curved shape that is concave with respect to a center of the first semiconductor chip.

10. The method of claim 8, wherein:
the first semiconductor chip, second semiconductor chip, package substrate and insulating layer form part of a package;
the first portion of the second redistribution line contacts the second conductive pad in a fan-in region of the package; and
the second portion of the second redistribution line contacts the first redistribution line in a fan-out region of the package.

11. The method of claim 1, wherein the insulating layer is a first insulating layer, and further comprising:
providing a second insulating layer surrounding side surfaces of the second semiconductor chip,
wherein the first insulating layer contacts the second insulating layer.

12. A method comprising:
providing a first semiconductor chip and a first insulating layer surrounding lateral sides of the first semiconductor chip;
providing a second semiconductor chip and a second insulating layer surrounding lateral sides of the second semiconductor chip;
providing a third insulating layer below the first semiconductor chip and first insulating layer, so that the first semiconductor chip is between the third insulating layer and the second semiconductor chip, the third insulating layer forming a package substrate;
providing a plurality of external connection terminals on the third insulating layer, such that the third insulating layer has a first surface facing the first semiconductor chip and a second surface facing the external connection terminals;
providing a first redistribution line on the first surface of the third insulating layer and extending horizontally along the first surface of the third insulating layer, the first redistribution line contacting a first conductive pad of the first semiconductor chip; and
providing a second redistribution line connected to a second conductive pad at a surface of the second semiconductor chip, the second redistribution line passing through the first insulating layer to contact the first redistribution line.

13. The method of claim 12, wherein the second redistribution line includes a first portion extending horizontally and a second portion extending vertically and horizontally through the first insulating layer.

14. The method of claim 13, wherein the second portion of the second redistribution line is formed along a boundary between two different insulative structures that form the first insulating layer.

15. The method of claim 14, wherein the second redistribution line is formed after forming a first of the two different insulative structures that form the first insulating layer, and is formed before forming the second of the two different insulative structures that form the first insulating layer.

16. The method of claim 15, wherein the second redistribution line is conformally formed on the first insulative structure, the second insulating layer, and the second semiconductor chip.

17. The method of claim 12, wherein the first redistribution line is formed before the third insulating layer.

18. The method of claim 12, wherein the second redistribution line contacts the second conductive pad at a surface of the second semiconductor chip that faces the first semiconductor chip.

19. A method comprising:
providing a second semiconductor chip surrounded by a second insulating layer;
forming a first insulative structure on the second insulating layer, the first insulative structure protruding from a surface of the second insulating layer;
conformally forming a second redistribution layer on the first insulative structure, the second insulating layer, and the second semiconductor chip, the second redistribution layer contacting a conductive pad on the second semiconductor chip;
mounting a first semiconductor chip on the second semiconductor chip;
forming a first insulating layer to fill a space between the first insulative structure and the first semiconductor chip; and
forming a first redistribution layer on the first semiconductor chip, the first insulating layer, and the first insulative structure, to contact the second redistribution layer.

20. The method of claim 19, further comprising:
forming a package substrate on the first redistribution layer; and
forming external connection terminals on the package substrate, so that the external connection terminals is electrically connected to the first redistribution layer.

21-44. (canceled)
